(19) United States
(12) Patent Application Publication
(10) Pub. No.: US 2024/0230783 A1
(43) Pub. Date: Jul. 11, 2024

(54) HEALTH MONITORING OF ELECTROCHEMICAL ENERGY SUPPLY ELEMENTS

(71) Applicant: Oxford University Innovation Limited, Oxford (GB)

(72) Inventors: David HOWEY, Oxford (GB); Antti AITIO, Oxford (GB)

(21) Appl. No.: 18/556,889

(22) PCT Filed: Apr. 22, 2022
(86) PCT No.: PCT/GB2022/051028

§ 371 Date: Oct. 24, 2023

(30) Foreign Application Priority Data
Apr. 27, 2021 (GB) 2105995.1
Feb. 24, 2022 (GB) 2202556.3

(51) Int. Cl. G01R 31/392; G01R 31/367; G01R 31/387; G01R 31/389

(52) U.S. Cl. CPC G01R 31/392; G01R 31/367; G01R 31/387; G01R 31/389

(57) ABSTRACT

Health of electrochemical energy supply elements is determined from sensor data representing sensed parameters of the electrochemical energy supply elements. A model of a health parameter that is dependent on operational parameters derivable from the sensor data and on health of the electrochemical energy supply element is fitted over the sensor data. The distribution of the health parameter is modelled as a Gaussian Process having an overall kernel combining a first kernel modelling dependency on the operational parameters and a second, non-stationary kernel modelling degradation over time. Health metrics over time for respective electrochemical energy supply elements are derived, comprising values of the health parameter that are predicted by the fitted model in respect of a predetermined operating point of the operational parameters. The health parameter is informative of the health of the electrochemical energy supply element and may be used as an input variable to a machine learning classifier.

The present invention relates to monitoring of the health of electrochemical energy supply clements, for example battery clements.

Electrochemical energy supply elements are used in an increasingly wide range of applications. The health of electrochemical energy supply elements generally degrades over time, for example due to degradation of the electrochemistry.

As an illustrative example solar off grid systems may be considered as follows. Hundreds of millions of people lack access to electricity. Decentralised solar-battery systems are key for addressing this global challenge whilst avoiding carbon emissions and local air pollution. To achieve universal electricity access, it is expected that the number of decentralised solar-battery systems and solar mini-grids will need to increase substantially, but this is inhibited by the relatively high costs and unreliability of batteries, sub-optimal battery lifetimes, and rural locations that inhibit timely preventative maintenance.

Accurate monitoring of battery health and prediction of failure from live operational sensor data could in principle improve user experience and reduce costs. But lack of controlled cycling, noise from low cost sensors means that existing lab-based techniques fail to work effectively for batteries or other electrochemical energy supply elements in the field.

Such monitoring of battery health and prediction of failure in real-world operating environments is desirable not only for operational safety and planning of maintenance, but also for improving design by understanding the impact of varying usage on battery life. Monitoring in the field is challenging because direct measurement of health using standardised performance tests is typically not possible due to the costs of the required service interruption and testing equipment. Therefore, monitoring and prediction should ideally be performed direct from monitored operational sensor data, typically being battery terminal voltage, temperature and current. However, this means that the controlled operating conditions that would normally ensure consistent health estimation in lab tests are missing. Further complication arises because the common health metrics (capacity and internal resistance) are both influenced by operating conditions. Finally, the current, voltage and temperature sensors used in many real-world applications are not of the same accuracy as those in laboratories, and data recording is often incomplete, resulting in substantial gaps in the time series.

Techniques for battery health estimation can broadly be classified into either model-based or data-driven methods. Model-based approaches typically use an electrical equivalent circuit model of a battery combined with techniques from feedback control to track internal states, such as state of charge, and parameters, such as internal resistance and capacity. Gradual evolution in the model parameters enables state of health estimation. Bayesian filtering or adaptive observers are common approaches. The choice of battery model is a trade-off between parsimony/computational resources, and accuracy/flexibility. Equivalent circuit models are ubiquitous and widely employed in electric vehicle battery management systems, but may suffer from a lack of accuracy across the wide range of operating points experienced in real world usage. Although higher fidelity ‘physics-based’ models derived from porous electrode theory are also available, these are generally considered too complex and computationally demanding for state of health tracking. Recent efforts to explore a compromise between flexibility and efficiency have resulted in reduced order physics-based models that may offer benefits compared to circuit models, although these still have a relatively large number of parameters and require domain knowledge for correct implementation.

In contrast, data-driven methods try to estimate the state of health of a battery directly from input features computed from the measured voltage, current and temperature data. For example, Richardson et al. [1] used input features extracted from the voltage curve under galvanostatic charging conditions to estimate capacity with Gaussian Process (GP) regression. You et al. [2] used neural networks and a support vector machine to map historical distributions of current, temperature and voltage to remaining capacity. Data-driven health estimation to date has been demonstrated using laboratory data under controlled conditions at relatively small scales. Publicly available laboratory generated datasets, such as ones available from NASA, University of Maryland, and Stanford University, contain only up to 124 cells.

Data-driven methods for health estimation show promise, but their ‘black-box’ nature reduces interpretability of results in comparison to model-driven approaches. Also, the preprocessing of input features required for some of the machine learning based SoH estimates should be avoided in online environments, giving preference to those methods using data readily available from battery management systems (BMSs) in order to reduce computational effort. Crucially, if battery charging and discharging patterns are highly dynamic, it might not be possible to calculate consistent features from current, voltage and temperature over the lifetime of the battery.

In real-world applications, a flexible and robust approach for battery SoH estimation and life prediction is required because of the severe constraints imposed by dynamic loading conditions, less accurate sensors, lack of controlled charge and discharge sequences and lack of prior knowledge of battery model parameters.

According to a first aspect of the present invention, there is provided a method of determining health of electrochemical energy supply elements in a set of electrochemical energy supply clements, the method comprising: receiving sensor data representing sensed parameters of the electrochemical energy supply elements over time; fitting a model of a health parameter of respective electrochemical energy supply clements over the sensor data, the health parameter being dependent on health of the electrochemical energy supply element and on operational parameters over time derivable from the sensor data, the model modelling the distribution of the health parameter as a Gaussian Process having an overall kernel that combines a first kernel that models dependency of the health parameter on the operational parameters and a second kernel that is a non-stationary kernel that models degradation of the health parameter over time; and deriving health metrics over time for respective electrochemical energy supply elements comprising values of the health parameter that are predicted by the fitted model in respect of a predetermined operating point of the operational parameters.

Thus, the present invention implements techniques from probabilistic machine learning that are robust to changing operating conditions and data gaps, specifically using a Gaussian Process regression model that estimates health trajectories from sensor data. The method evaluates the dependency of the health parameter on the instantaneous values of operational parameters, for example current, temperature and state of charge, which represent operating conditions and may be derived from the sensor data.

The overall kernel of the Gaussian Process combines a first kernel and a second kernel. The first kernel models dependency of the health parameter on the operational parameters and thereby provides for a variability of the health parameter with instantaneous operational parameters that is relatively smooth, as defined by the hyperparameters of the first kernel. On the other hand, the second kernel is a non-stationary kernel and models degradation of the health parameter over time enabling degradation at beginning of monitoring to grow as the electrochemical energy supply clement ages. This means that extrapolation of future health beyond the learned data tracks the learned trajectory instead of reverting to the prior mean.

The use of the first kernel makes it possible to derive health metrics over time that comprise values of the health parameter that are predicted by the fitted model in respect of a predetermined operating point of the operational parameters. This effectively provides calibration of the health parameter to the same standard conditions at all time points, which would not be observable in the instantaneous value of the health parameter. This results in smooth estimates of a health metric that provides meaningful information on the health of the electrochemical energy supply element. As shown in the First Example detailed below, this allows the present invention to provide an understanding of health of electrochemical energy supply clements, extend lifetime and improve performance in real-world applications.

The combination of the first kernel and the second kernel may be addition or multiplication.

The benefit of combination by addition is that the computational efficiency of the analysis is improved. The benefit of combination by multiplication, in some circumstances, is that it may be possible to represent a more complex dependency of the health metric on operational parameters over the lifetime of the electrochemical energy supply clement. The form of the combination may be chosen accordingly. For example, if a health metric has a dependency on operating parameters that is not constant over the lifetime of the supply clement, a multiplication of the two kernels may provide greater accuracy. In this case, the health metric at each operating point is allowed to evolve freely. On the other hand, if the operating point dependency is constant over lifetime, an addition of two kernels may be used, which is computationally cheaper as it assumed that the health metric evolves identically over the operational parameters. The present method may be applied in general to any type of electrochemical energy supply element in which electrochemical processes are used to supply energy.

One particular type of electrochemical energy supply element to which the method may be applied is a battery element. A battery element may comprise one or more electrochemical cells that electrochemically store energy for supply as electrical current. Two suitable types of battery element are a lead-acid battery element or a lithium-ion battery clement, but the method may be applied to other types of battery element, such as a redox flow battery element. The battery element may in general be for any application, for example automotive starter batteries, electric vehicle batteries, or for local and/or grid energy storage.

The present method may also be applied to types of electrochemical energy supply clement other than a battery element, for example a fuel cell element or an electrochemical capacitor element. A fuel cell element may comprise one or more electrochemical cells that electrochemically generate energy from a fuel for supply as electrical current. An electrochemical capacitor may comprise an electrical double layer formed forms at the interface between an electrolytic solution and an electronic conductor, which stores energy for supply as electrical current. An electrochemical capacitor may be, for example, a charged carbon-carbon system or a carbon-battery electrode and conducting polymer electrode combinations sometimes called an ultracapacitor, supercapacitor, or hybrid capacitor.

The electrochemical energy supply element may be any unit of an energy supply system for which sensor data is available, for example a single electrochemical cell, a module comprising plural electrochemical cells, or an assembly of modules, depending on the construction.

The health parameter may in general be any parameter that is dependent on health of the electrochemical energy supply element. In one example, the health parameter may be internal resistance. In another example, the health parameter may be capacity of the electrochemical energy supply element.

The sensed parameters may in general be of any type. In one typical example, the sensed parameters may be voltage, current and temperature.

The operational parameters may in general be any operational parameters on which the health parameter depends. In general, any of the operational parameters may be the sensed parameters directly represented by the sensor data or may be derived by calculation from the sensed parameters. The operational parameters may be chosen in accordance with the nature of the electrochemical energy supply element and the health parameter. In the case of that the electrochemical energy supply element is a battery element and the health parameter is internal resistance, the operational parameters may be current, temperature and a state of charge.

When used, the state of charge may be a material property, for example a concentration of material in the electrochemical energy supply element. In some applications, the state of charge may be a sensed parameter represented by the sensor data. In other applications, the state of charge may be derived by calculation from the sensed electrical parameters using Coulomb counting.

When the electrochemical energy supply element is chargeable, such as a battery clement, the method may further comprise selecting segments of the sensor data that represent charging of the electrochemical energy supply element, so that the model of the health parameter is fitted to the selected segments of the sensor data. In some applications the charging segment may provide higher currents and/or variation in voltage, which may increase the accuracy of the health parameters derived therefrom, thereby improving performance of the method and/or reducing the amount of data required for fitting.

The model will now be considered.

The first kernel that models dependency of the health parameter on the operational parameters may be a kernel that has non-zero prior variance over the entire input space. The first kernel may be a stationary kernel, for example a rational quadratic kernel or a kernel in the Matern family of kernels, preferably a squared exponential kernel. Use of such kernels has an advantage that the concept of the length scale exists meaning that fitting is relatively straightforward.

The second kernel that is a non-stationary kernel that models degradation of the health parameter over time may be any kernel with zero initial variance. The second kernel may be a kernel representing any order of integration of the Wiener Process or a polynomial kernel of any order. Use of a first order integrated Wiener Process kernel has the advantage that it is very fast to evaluate.

The fitting of the model of the health parameter may be performed using a recursive estimation framework which provides for efficient processing.

The fitting may output a posterior predictive distribution of the health metric and a posterior estimate of hyperparameters of the overall kernel, which may be used in the derivation of the health metric.

There are various options for the hyperparameters, for example as follows.

One option is that the hyperparameters are specific to each electrochemical energy supply element. In that case, the hyperparameters may be fitted over the sensor data of respective electrochemical energy supply elements in the set. Use of hyperparameters that are specific to each electrochemical energy supply element may improve the fitting, thereby providing a health metric which is an accurate representation of the health of the electrochemical energy supply element.

Another option is that the hyperparameters are common to all electrochemical energy supply elements. In that case, the hyperparameters may be fitted over the sensor data of all the electrochemical energy supply elements in the set during fitting of the model, or may have predetermined values, for example having been previously derived from a training data set that is representative of the population of the electrochemical energy supply elements. Use of hyperparameters that are common to all electrochemical energy supply elements may improve the performance of the health metric when used as input variables in a classification process, for example as described further below.

The values represented by the health metric may comprise absolute values of the health parameter and/or partial derivatives of the health parameter with respect to time. Use of partial derivatives of the health parameter with respect to time, especially when used in combination of with the absolute value, may improve the information content of the health metric, for example improving the performance when used as input variables in a classification process, for example as described further below. This is because the partial derivatives with respect to time may indicate important processes relevant to the health of the electrochemical energy supply clement, for example in the case of a battery element a ‘knee-point’ in degradation that is the onset of accelerated degradation towards end-of-life.

The derived health metric may be used to predict faults of electrochemical energy supply clements in a test set. In this case, the method of deriving the health metric is performed in respect of the electrochemical energy supply elements in the test set to derive the health metrics in respect of the test set. Then the electrochemical energy supply elements may be classified with a machine learning classifier that uses the derived the health metrics over time as input variables, into a plurality of classifications representing presence and absence of predicted faults. The prediction may be prediction of a current fault (i.e. diagnosis of the current state) or a future fault (i.e. prognosis of a future state).

Optionally, the machine learning classifier may classify the electrochemical energy supply clements on the basis of both the derived the health metrics and also values derived from the sensed data of at least one stress factor for respective electrochemical energy supply clements, being a factor affecting the health of the electrochemical energy supply element.

The machine learning classifier may comprise a Gaussian Process classifier that uses health metrics over time and classification labels in respect of electrochemical energy supply elements in a training set. The training set is a set of electrochemical energy supply elements that has been previously monitored. It may be a different set of electrochemical energy supply clements from the test set, or the two sets may be the same or overlap if earlier sensor data from the same electrochemical energy supply elements is used. The classification labels represent the presence and absence of faults in the training set, for example on the basis of servicing information about the electrochemical energy supply elements.

In this case, the health metrics over time in respect of the electrochemical energy supply elements in the training set may be predetermined, for example having been derived from the training data set previously to processing sensor data from the test set, or alternatively may be derived using the method in accordance with the present invention in respect of the electrochemical energy supply elements in the training set, at the same time as using the method in accordance with the present invention in respect of the electrochemical energy supply clements in the training set.

However, use of a Gaussian Process classifier is not essential, and in general the machine learning classifier may be of any type, for example a decision tree classifier, a logistic regression classifier, a K-nearest neighbour classifier, a neural network classifier or a support vector machine classifier.

The classifications may be used as the basis for servicing the electrochemical energy supply elements, for example by repairing or replacing electrochemical energy supply elements in classifications representing the presence of a predicted fault.

According to further aspects of the present invention, there may be provided a computer program that is capable of execution in a computer apparatus to cause the computer apparatus to perform a method corresponding to the first aspect of the present invention, a computer-readable storage medium storing such a computer program, or a computer apparatus arranged to implement a similar method to the first aspect of the present invention.

To allow better understanding, embodiments of the present invention will now be described by way of non-limitative example with reference to the accompanying drawings, in which:

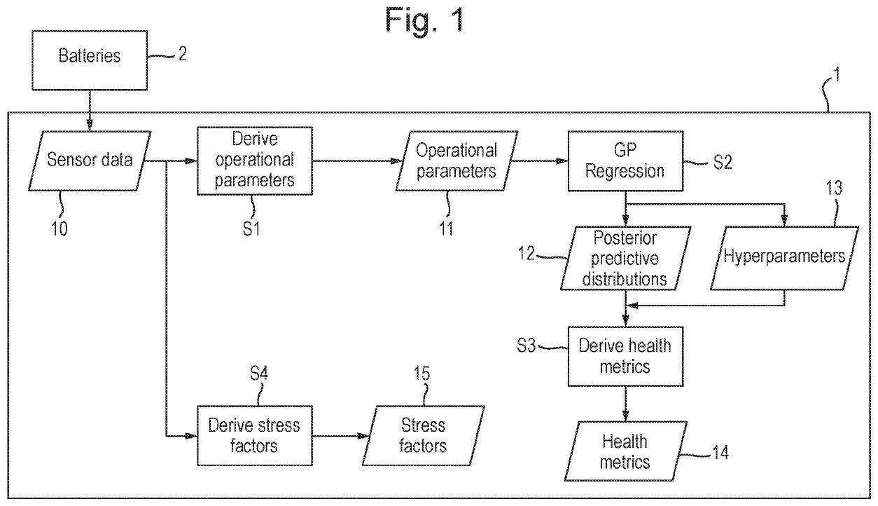

FIG. 1 is a block diagram of a method of deriving a health metric;

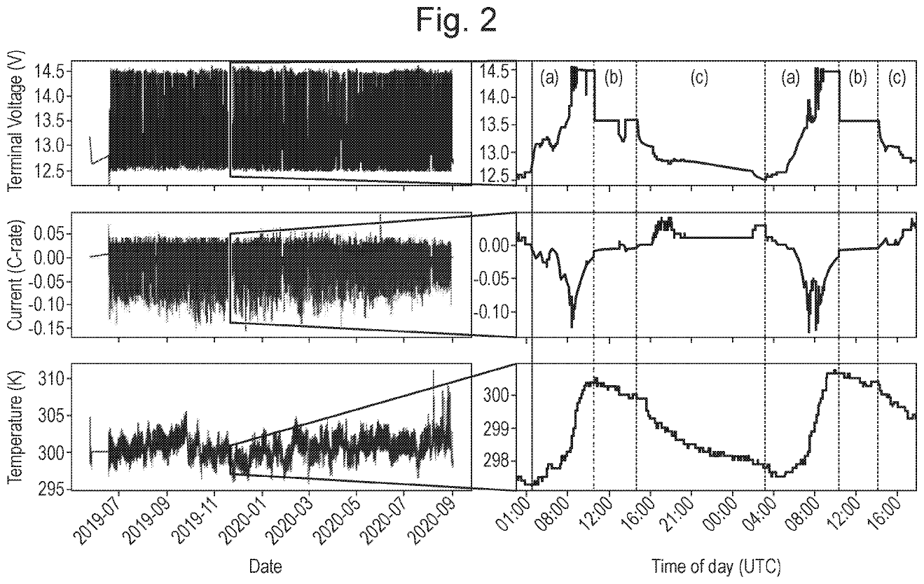

FIG. 2 is a set of graphs of typical diurnal load pattern for solar connected lead-acid batteries in a First Example, in particular solar charge, float charge, discharge;

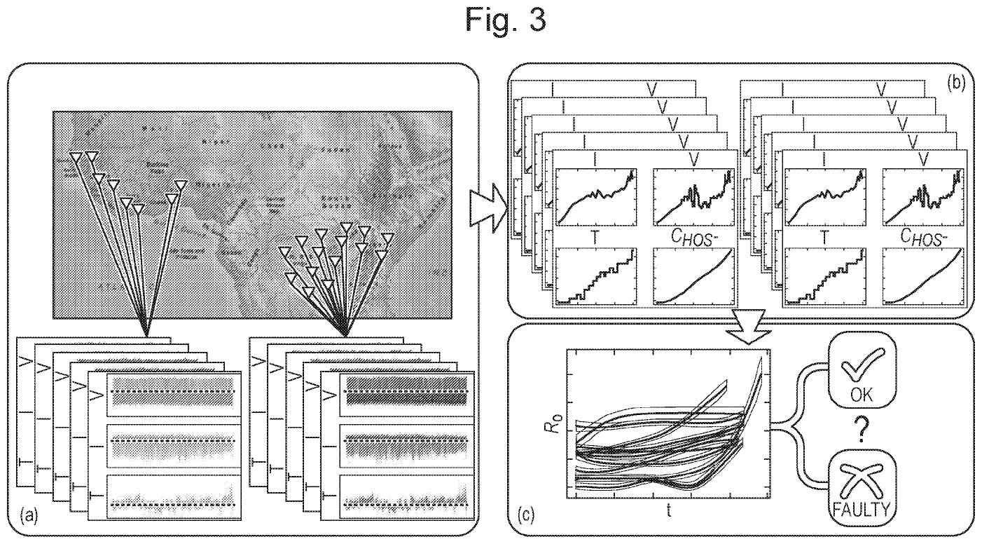

FIG. 3 is a schematic view of the overall workflow in the First Example, including (a) data for PV-connected VRLA batteries containing 5.89×10⁸ rows of current, voltage and temperature data recorded at a variable frequency, (b) sub-sampled data for computational efficiency to yield a dataset of 16.22×10⁶ rows of evenly sampled data from approximately 100 charging segments over the lifetime of the battery, and (c) the application of GP regression to obtain estimates for internal resistance over the lifetime of each battery at a constant operating point and faulty/non-faulty GP classification several weeks prior to the end of each time series;

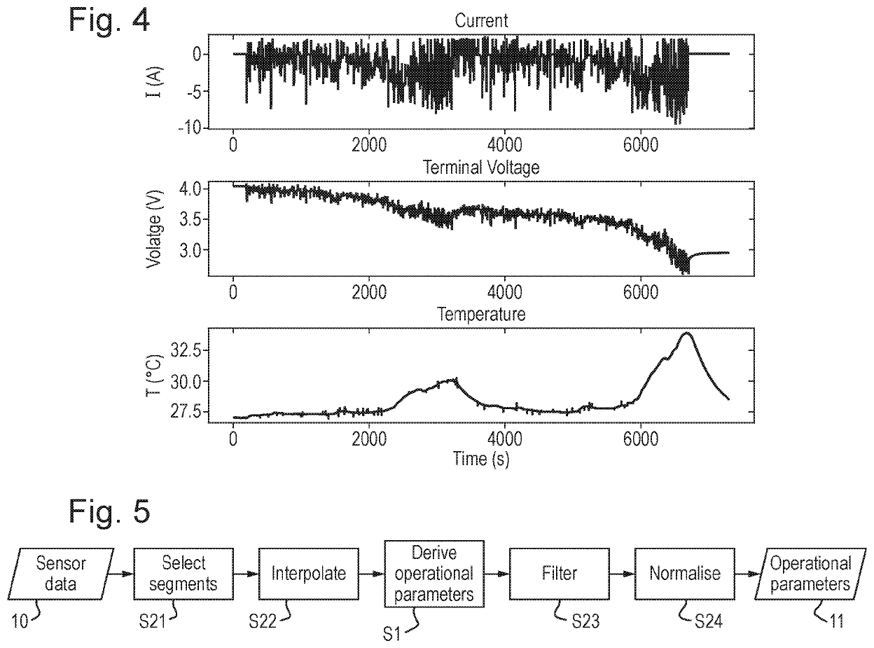

FIG. 4 is a set of graphs of typical patterns over the drive cycle for Lithium-ion batteries in a Second Example, in particular current, voltage and temperature;

FIG. 5 is a block diagram of a method of deriving operational parameters from sensor data;

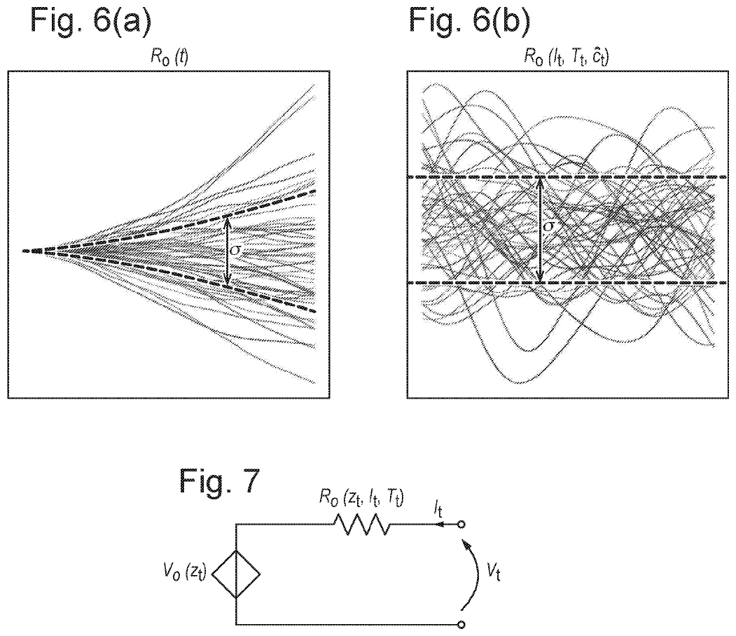

FIG. 6 are graphs of draws from (a) a non-stationary Wiener velocity process and (b) a stationary squared exponential process with short scale smoothness, wherein dotted lines show 1σ bound;

FIG. 7 is a circuit model of a battery having no reactance;

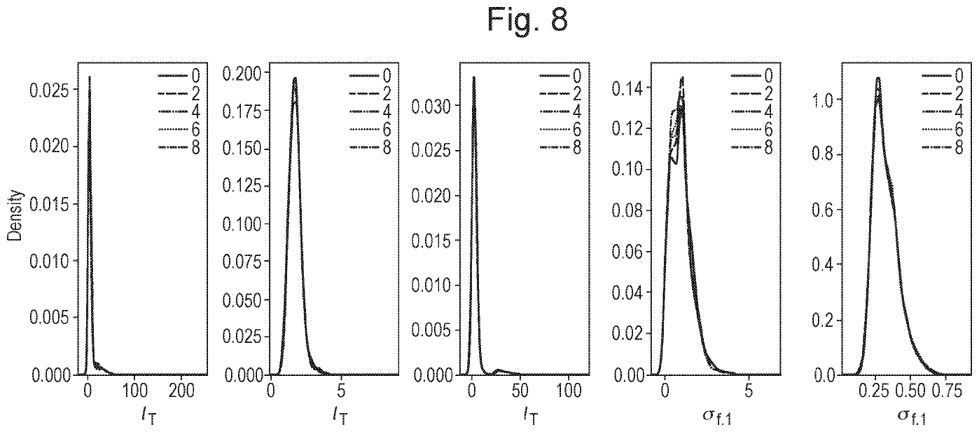

FIG. 8 is a set of graphs of distributions of hyperparameter for respective data cutoffs across the population;

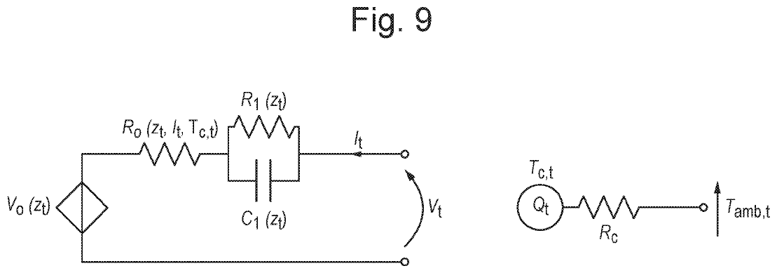

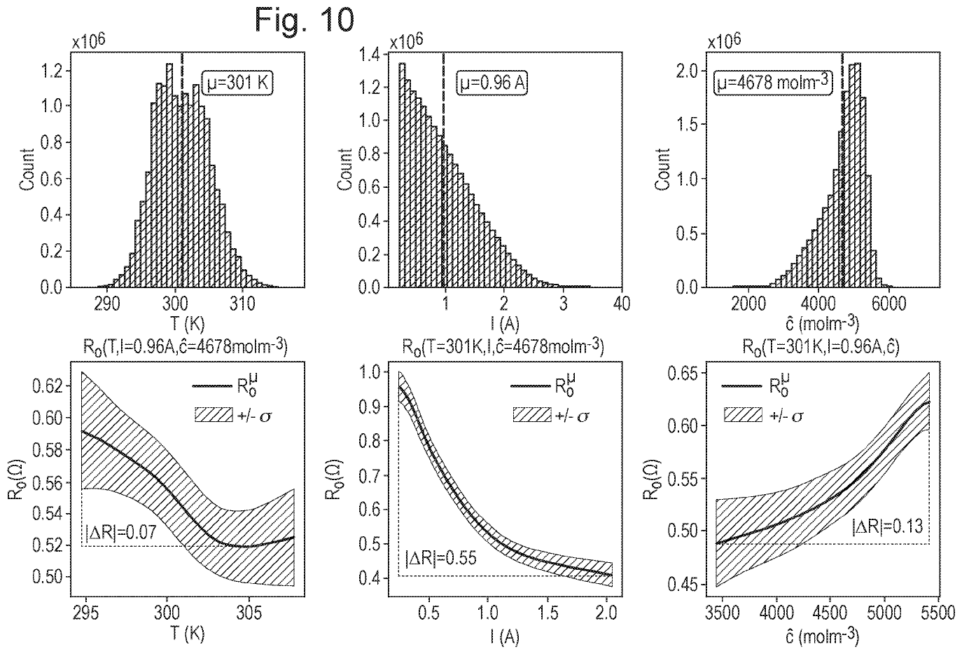

FIG. 9 is a circuit model of a battery having a capacitive reactance in parallel with part of the internal resistance and a thermal model of the battery;

FIG. 10 shows a set of graphs, the top row showing operating points in terms of temperature, current and acid concentration for all batteries in the downsampled dataset of the First Example and the bottom row showing 1-D projections of internal resistance R₀ as a function of each variable between the 5th and 95th percentile, while keeping other two constant at the population means;

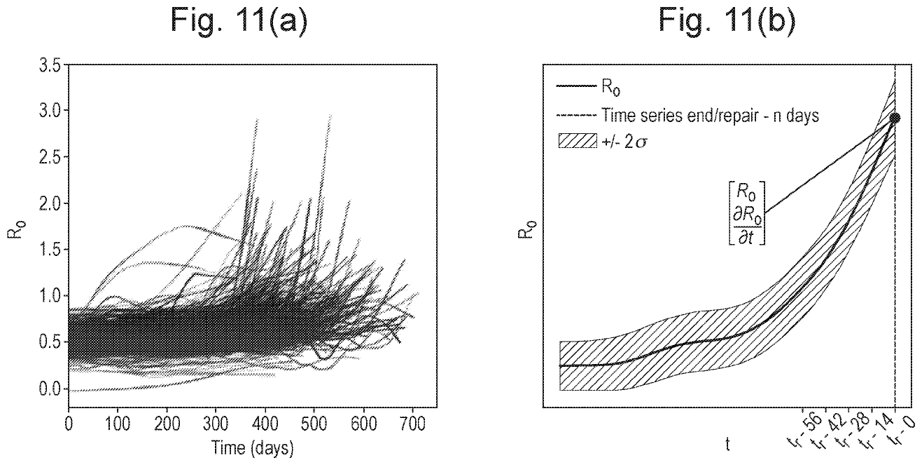

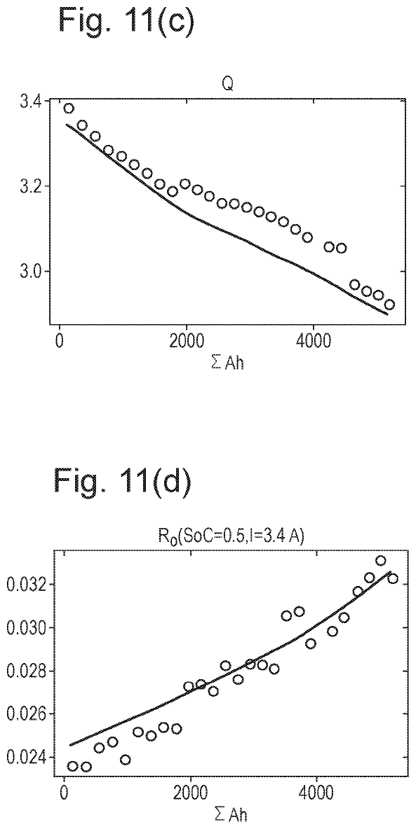

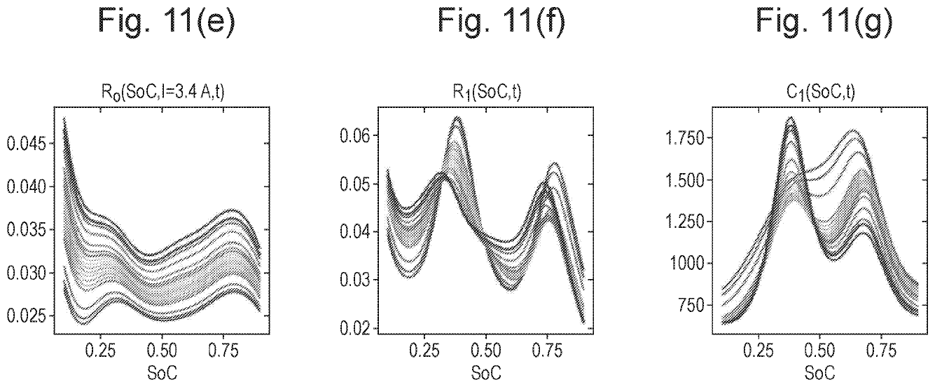

FIGS. 11(a) and (b) are graphs of the First Example, wherein FIG. 11(a) shows internal resistance after the normalisation of with respect to the operating point to estimate the evolution of internal resistance for each battery at the common operating point, FIG. 11(b) shows features calculated from the internal resistance timelines for diagnosis and prognosis purposes include the GP mean and the its gradient with respect to time with data cut off at 0,14,28,42 and 56 days from the end of the data series for each battery;

FIGS. 11(c) to 11(g) are graphs of the Second Example, wherein FIGS. 11(c) and 11(d) are graphs of capacity and internal resistance R0 against the total Ampere-hour throughput over lifetime, showing estimated values (line) vs values measured in a lab (scatter points), and FIGS. 11(c)-(g) are graphs of series resistance R0, R1 derived from alpha in the circuit dynamic, and C1 derived from beta in the circuit dynamic, as a function of the state of charge at constant current, each line representing a different point in time from the beginning to the end of the ageing campaign;

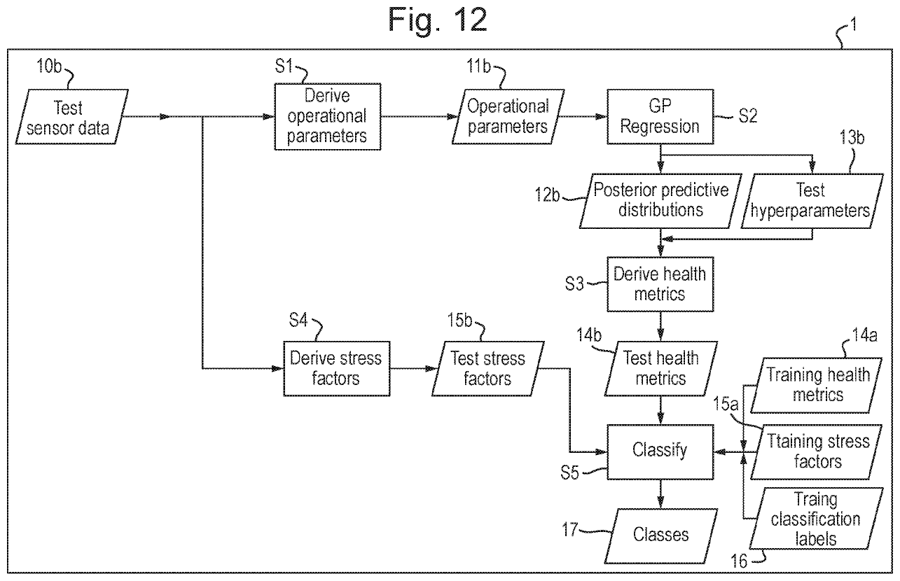

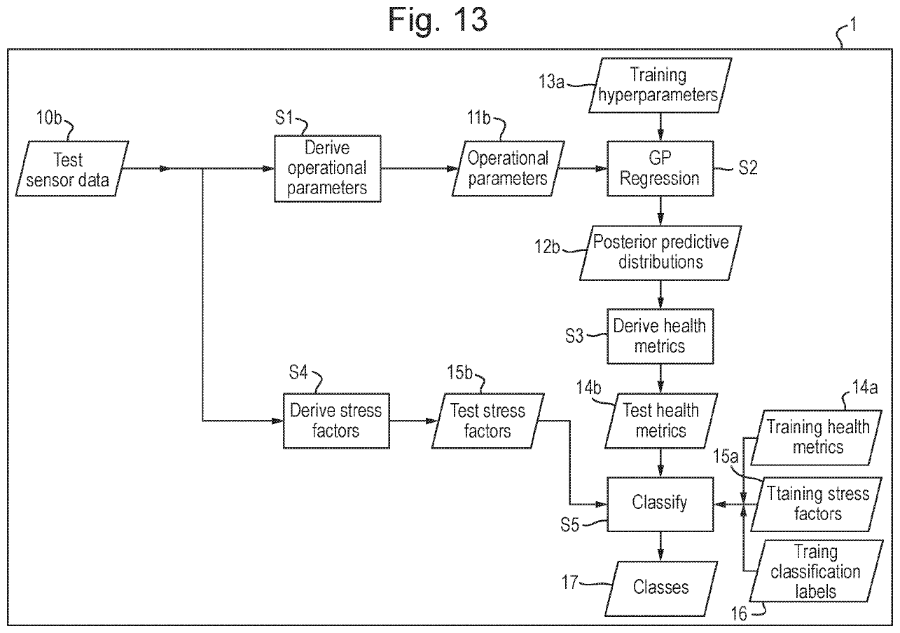

FIGS. 12 and 13 are block diagrams of two alternative methods of predicting faults of batteries in a test set;

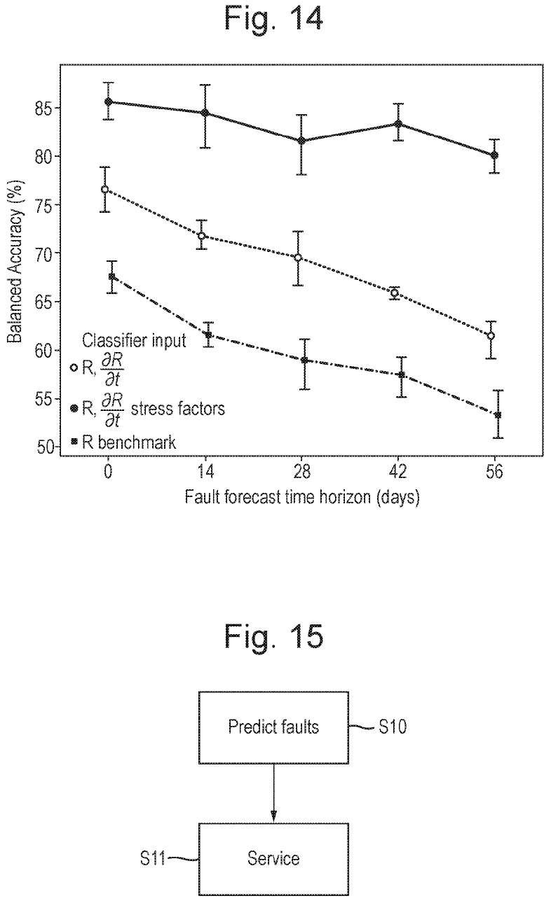

FIG. 14 is a graph of classification performance of the First Example in terms of balanced accuracy for time horizons 0-56 days from battery time series end, the error bars showing standard deviations across stratified 5-fold cross validation test sets; and

FIG. 15 is a flowchart of a method of servicing a test set of electrochemical energy supply elements.

FIGS. 1, 5, 12 and 13 illustrate methods performed in a computer apparatus 1. In these drawings, the steps of the method are performed in functional blocks of the apparatus (shown as rectangles). The functional blocks process data (shown as parallelograms) representing various information described in detail below. The method is performed as follows.

The computer apparatus 1 may be implemented as a computer apparatus executing a computer program. In this case, the computer program is capable of execution by the computer apparatus and is configured, on execution, to cause the computer apparatus to perform the method including the steps of the functional blocks. Such a computer apparatus may be any type of computer system but is typically of conventional construction. The computer program may be written in any suitable programming language.

The computer program may be stored on a computer-readable storage medium, which may be of any type, for example: a recording medium which is insertable into a drive of the computing system and which may store information magnetically, optically or opto-magnetically; a fixed recording medium of the computer system such as a hard drive; or a computer memory. In some embodiments, portions of the computer program may be implemented using hardware amenable to parallelisation of calculations such as a Graphics processing unit (GPU).

Without loss of the generality of FIGS. 1, 5, 12 and 13, there will also be described a First Example and a Second Example of the application of the methods performed on datasets and described in further detail below.

The methods relate to batteries 2 in a set of batteries 2. The batteries 2 are examples of electrochemical energy supply elements. In the First Example, the batteries 2 are lead-acid batteries, whereas in the Second Example, the batteries 2 are lithium-ion batteries. However, the methods may equally be applied to any type of electrochemical energy supply element, as discussed above. The health of such electrochemical energy supply clements degrades over time, for example as the electrochemistry degrades.

FIG. 1 shows a method of determining health of the batteries 2 in the set of batteries 2. Sensor data 10 representing sensed parameters of the batteries 2 over time are received by the computer apparatus 1.

The method of FIG. 1 is generally applicable to a set of batteries 2 that is a test set or a training set. The sensor data 10 and other data in the method is labelled without a suffix for this general case, but is with a suffix a for the training data and with a suffix b for the test data, for example sensor data 10a relating to the training set and sensor data 10b relating to the test set.

In the First Example, the batteries 2 are 1117 lead-acid batteries, cach with nominal voltage 12 V (internally comprising 6 cells in series), nominal capacity 17 Ah, and attached to a 50 Wp photovoltaic panel. These systems were provided by BBOXX Ltd. and located across Kenya, Rwanda, Togo, Guinea, Ivory Coast, Mali, Senegal and the Democratic Republic of Congo. Each battery was in use for 400-735 days, giving a dataset totalling more than 500 million rows of data (around 45 GB). This dataset is a small subset of the total number of BBOXX systems deployed, and was selected to ensure that each time series was at least 400 days in length and also that the set contained approximately the same number of failed versus non-failed batteries. Examples of the loading patterns experienced by the batteries 2 in the dataset are highlighted in FIG. 2. The sensor data 10 of the First Example is also shown schematically in FIG. 3(a).

In the Second Example, the batteries are lithium-ion single cells (in particular Samsung INR18650-35E) which are subjected to repeated drive-cycle load patterns interspersed with constant current-constant voltage chargings, and periodic check-up tests, all conducted in a thermal chamber in lab conditions. The dataset is publicly available, as disclosed in [16]. The current, voltage and temperature patterns over the drive cycle are

shown in FIG. 4. A check-up test to estimate discharge capacity and internal resistance was conducted in every 30 drive cycles.

In the method of claim 1, the sensed parameters are voltage (for example battery terminal voltage), current and temperature. More generally, the sensed parameters represented by the sensor data 10 may in general be of any type, as available for the batteries 2 or more generally electrochemical energy supply elements.

In step S1, operational parameters 11 are derived from the sensor data 10. As discussed further below, in FIG. 1 the operational parameters 11 are used to derive internal resistance of the batteries 2 which is an example of a health parameter of the batteries 2. More generally, any health parameter on which on health of a battery 2 depends could be used, including for example the capacity of a battery 2, which is often inversely correlated with internal resistance.

In lead-acid systems, internal resistance may be preferable, since the main failure mechanism is likely to be resistance increase rather than capacity fade, but without loss of ability to apply the present methods to capacity.

In lithium-ion systems, capacity may be preferable, since in many real-world applications the fade in total energy delivered per discharge (which depends on Ampere-hour capacity more than internal resistance) is more important than the power that can be delivered at (which depends on the internal resistance).

In the method of FIG. 1, the operational parameters 11 are temperature, current and state of charge of the batteries 2. Temperature and current are sensed parameters directly represented by the sensor data 10 and state of charge is derived by calculation from the sensed parameters as discussed further below. More generally, the operational parameters 11 could be any parameters chosen in accordance with the health parameter as parameters which may be derived from the sensed parameters. In the general case, any of the operational parameters 11 may be the sensed parameters directly represented by the sensor data 10 or may be derived by calculation from the sensed parameters.

The method of processing the sensor data 10 to derive the operational parameters 11 which is used in FIG. 1 is shown in greater detail in FIG. 5.

In step S21, segments of the sensor data 10 are selected. The segments may be, for example, segments that represent charging of the respective batteries 2 or segments that represent discharging of the respective batteries 2. The nature of the segment may be chosen having regard to the nature and properties of the batteries. This selection reduces the amount of sensor data 10 that is subsequently processed.

In the case that the batteries 2 are lead-acid batteries, it may be desirable, but not essential, to select segments that represent charging of the respective batteries 2 for the following reasons.

Measured current, voltage and temperature profiles of batteries 2 provide some particular challenges for battery health diagnosis. Firstly, depth of discharge is commonly quite small, with the 99th percentile being 54% across discharge segments (defined as continuous discharge of over 5% DoD), making it difficult to observe changes in the discharge voltage curve caused by capacity changes as the cell ages. Secondly, since average charging and discharging currents are small (99th percentile approximately 0.1C, where C indicates the charge or discharge current, specified by the manufacturer, to fully charge or discharge the battery in 1 hour) and often constant, estimation of internal resistance is numerically poorly conditioned, in other words small errors in measured voltage cause large errors in estimated resistance. These difficulties are compounded by unknown sensor accuracy.

Furthermore, the average currents, temperatures and depths of discharge vary over time and across the population of batteries 2. Charging segments typically provide a more varied and higher amplitude input signal for estimation of internal resistance compared with discharging segments, where the current is on average small and relatively constant. The choice of internal resistance measured during charging segments as the health parameter therefore provides a methodology for health diagnosis that is robust to changes in usage and that does not require controlled diagnostic tests.

On the assumption that the state of health of each battery evolves smoothly over time, it is not necessary to select every single charging segment. Such down-sampling in step S21 reduces the computational requirements. For example, the reduction is by a factor of about 30 in the First Example, without compromising the fidelity of the health estimates.

In the First Example, around 100 suitable charging segments equi-spaced over the lifetime of the battery 2 were selected which reduced the computational requirements, by a factor of about 30. The conditions for selection are listed in the following table:

| Charging segment duration | >6000 | s |
|---|---|---|
| Starting voltage range | 11.5 V-12.5 V | |
| Starting current | <0.1 | A |
| max(Voltage in segment) | >14 | V |
| max(Time gap in recorded data) | <610 | s |

The conditions were used to filter down those charging segments with a reasonable range in state of charge. Additionally, each charging segment was truncated to include voltages up to 14 V. This was due to increased uncertainty in the open loop Coulomb counting method described below due to the magnitude of the side reactions increasing exponentially with terminal voltage.

In the case that the batteries 2 are lithium-ion batteries, it may be desirable, but not essential, to select segments that represent charging of the respective batteries 2. In applications using lithium-ion batteries, such as for an electric vehicle, the discharge pattern may be much more interesting and informative as it is a drive cycle, whereas charging is usually CC-CV (constant current until a constant voltage limit is reached).

In the Second Example, as the dataset has check-up tests every 30 drive cycles, the data is down-selected such that discharge segments corresponding to the last drive-cycle preceding the check-up were selected each time. In real-world operation, the frequency of the downsampled data is similar in both lithium-ion and lead-acid systems.

In step S22, the sensor data 10 of the selected segments is interpolated. Any suitable interpolation technique may be applied.

In the First Example, the data was interpolated to a 1-minute time grid using piece-wise cubic hermite interpolation [10].

In the Second Example, the data was also interpolated using cubic hermite interpolation [10], to a 1-second time grid.

In step S1, the operational parameters 11 are derived. The operational parameters 11 of temperature and current are simply selected from the sensed parameters which are directly represented by the sensor data 10. The operational parameters 11 of state of charge is derived by calculation from sensed parameters represented by the sensor data 10, as follows.

Firstly, an experimentally determined open circuit voltage function is inverted at a point in the charging curve where current is equal to its minimum. Following this, a Coulomb counting method is used to infer the acid concentration across the charging segment using the measured current. The required open-circuit voltage curve may be determined experimentally using a galvanostatic intermittent titration technique test (GITT), e.g. using in the First Example a Biologic SP-150 potentiostat placing the battery in a thermal chamber at 25° C. From this data, the electrolyte volume is also inferred by a least squares fit of the experimental curve.

An estimate for the electrolyte volume for the batteries 2 in the set is obtained by a least squares fit of experimentally determined open circuit voltage (OCV) curve and a commonly used OCV curve for lead acid cells. In the First Example, we carried out a GITT test with 20 1 hour C/20 discharge segments with a 2 hour rest in between at 25° C. To determine the electrolyte volume, the change in electrolyte concentration over discharge is given by

$$Δ {c}_{( {HSO}_{4}^{-} )} = I Δ t / ( {V}_{elec} F ) ,$$

where V_{elec} is the electrolyte volume and F is Faraday's constant and the OCV is expressed as a function of acid molality m as

$${V}_{cell} ( m ) = 1.922 + 0.148 {log}_{10} ( m ) + 0.064 {log}_{10}^{2} ( m ) + 0.074 {log}_{10}^{3} ( m ) + 0.034 {log}_{10}^{4} ( m )$$

with a simple conversion from molality to molarity given by

$$m = ( {V}_{w} {c}_{( {HSO}_{4}^{-} )} ) / ( ( 1 - {c}_{( {HSO}_{4}^{-} )} {V}_{e} ) {M}_{w} ) ,$$

where c_{(HSO}_{₄}_{^{−}}₎ is acid molarity, V_{w}, Vₑ and M_{w} the partial molar volumes of water and acid, and the molar mass of water respectively. The experimentally measured OCV curve which is a function of the Coulomb count, may be case as a function of acid concentration. To find the optimal value of V_{elec} the curve may be inverted at a point in the middle of a range, followed by a least squares fit over the range to match the gradient, which is inversely proportional to V_{elec}. In the First Example, the optimal value for V_{elec} was found to be 143 cm³. The OCV may be parameterized using a cubic polynomial as a function of acid molarity, or in any other suitable manner, as the shape of an OCV for a lead-acid system lends itself to a low order polynomial fit. In the First Example, as the measured temperature range we observed in the dataset is was approximately 10 K and the sensitivity of the OCV is of the order of 0.1 mV/K/cell, we ignored its temperature dependency.

The acid concentration for the segment is obtained Coulomb counting from the measured current data together with accounting for the known side reactions in lead-acid systems with a lumped term for the gassing reactions [7], using the relation

$$\frac{d \hat{c}}{dt} = \frac{{I}_{t} - {I}_{gas , 0} {e}^{{c}_{T} ( {T}_{t} - {T}_{0} ) + {c}_{V} ( {V}_{t} - {V}_{0} )}}{{FV}_{elec}}$$

where Iₜ, Tₜ, Vₜ are the measured current, temperature and terminal voltage, F is Faraday's constant, V_{elec} the estimated electrolyte volume and the gassing current parameters I_{gas,0}, c_{T}, T₀, c_{C}, V₀ set to those given by [7]. The substantial uncertainty due to the variation in these parameters over the lifetime of the battery is taken into consideration by projecting the input uncertainty in the acid concentration ĉ to measurement noise variance in GP regression.

In step S23, the data points are filtered to improve conditioning and to make sure the open-circuit voltage was consistent. In the First Example, data points where Iₜ<0.2 A or V_{OC,t}>Vₜ where filtered out.

In step S24, the data is normalized. Any suitable normalization technique may be applied, for example using the population-level moments, so that

$$X = \frac{x - \overline{x}}{{σ}_{x}} , x ∈ \{ {T}_{t} , {I}_{t} , {\hat{c}}_{t} \} \qquad [ eqn : normalize ]$$

where x⁻ and σₓ represent the population mean and variance in the down-sampled dataset. A normalised time-scale may be obtained by division of the time since beginning of life in seconds, e.g. by 400×86400 s in the First Example, bringing it to a similar range as the other inputs. The method of normalisation ([eqn:normalize]) may also used for the inputs used in the GP classifier.

In the First Example, these processes resulted in an average of 14500 rows of data for each battery 2. The operational parameters 11 of the First Example are shown schematically in FIG. 3(b).

Steps S2 and S3 are performed to estimate health metrics 14, which are values of a health parameter, as described in more detail below. In general, the health parameter may be any parameter that is dependent on health of the electrochemical energy supply element, but the following description is given with respect to an example in which the health parameter is internal resistance of the electrochemical energy supply element and an example in which the health parameter is capacity of the electrochemical energy supply element.

The internal resistance of all batteries depends on age, current, temperature and state of charge. In lead-acid cells the reasons for this include non-linear kinetics, nucleation and dissolution of lead sulfate, hydrolysis during charging, and degradation mechanisms such as sulfation, loss of active material and electrode corrosion. Comprehensively modelling the physics of all of these processes results in a model with a large number of parameters and it is not possible to identify them from field data. Instead, the present method uses machine learning techniques to learn the dependency of internal resistance on other factors. As will now be described, a Bayesian approach is used, expressing the internal resistance as a Gaussian Process over the operational parameters 11 and time.

In particular, in step S2 a GP regression is performed to fit a model of the health parameter of respective batteries 2 over the sensor data 10. The model models the distribution of the health parameter as a Gaussian Process (GP). Gaussian Processes are a flexible probabilistic technique for fitting functions to data [3], and they make very few assumptions about the structure of the underlying data.

As the health parameter (for example internal resistance or capacity) is dependent on the operational parameters 11 over time and on health of the battery 2, the GP has an overall kernel that combines a first kernel and a second kernel, where the first kernel models of the health parameter on the operational parameters and the second kernel is a non-stationary kernel that models degradation of the health parameter over time. In the method of FIG. 1, the first kernel is a standard squared exponential (SE) kernel, for example as shown in FIG. 6(b), and the second kernel is a Wiener velocity kernel, for example as shown in FIG. 6(a). In the Second Example, the first kernel is a rational quadratic kernel and the second is also a Wiener velocity kernel.

Nonetheless, in general other first and second kernels may be used, as discussed above.

The first kernel may reflects an assumption that the variability of resistance with instantaneous temperature, state of charge and current should be relatively smooth.

However, the second kernel is a non-stationary kernel, which enables degradation at beginning of life to be zero for each individual battery 2, and then to grow as the battery 2 ages. Using a non-stationary kernel means that extrapolation of future health of the battery 2 beyond the learned data tracks the learned trajectory instead of reverting to the prior mean.

The combination of the first kernel and the second kernel may be addition or multiplication.

In the case of combination by addition of the the first kernel and the second kernel, the two kernels are independent. Such an assumption that the resistance is the sum of two independent processes improves computational efficiency substantially, albeit at the expense of decoupling the dependence of resistance on temperature, state of charge and current from its dependence on age.

In the case of combination by multiplication of the the first kernel and the second kernel, the computations are more expensive but the model is more flexible, which may provide greater accuracy in some circumstances.

Gaussian Process models have ‘hyperparameters’ that describe the smoothness, magnitude, periodicity and so on of the data being modelled. Fitting a Gaussian Process to the sensor data 10 involves two steps estimation of values of the hyperparameters 13 and of the posterior predictive distributions 12 (i.e. mean and variance) of the model of the health parameter. Both of these derivations can be computationally expensive, each by default scaling with [symbol] (n³), where n is the number of data points being fitted [3]. To overcome this challenge, the GP regression may be performed using a recursive estimation framework [4], [5] and distributed computation [9].

Examples of step S2 will now be described in detail.

First, there will be described an example of step S2 suitable for batteries 2 that are lead-acid batteries (or more generally lead-acid electrochemical energy supply elements). In this example, the health parameter is internal resistance and the Gaussian model incorporates a simple circuit model of the battery 2 as shown in FIG. 7. This circuit model models the battery 2 in accordance with Ohm's law as having the internal resistance without reactance. In general, in any embodiment of the present invention, the Gaussian Process may use such a circuit model of the battery.

This example is suitable for data that is typically available from operational telemetry available for lead-acid batteries attached to small-scale photo-voltaic systems. This will now be described in detail.

Given that the C-rates during charging are low (<0.2 C), we may ignore the effect of concentration overpotentials. Therefore terminal the voltage prediction is given by the sum of the open circuit voltage and a lumped linearised internal resistance term,

$${V}_{t} = {V}_{OC} ( {\hat{c}}_{t} ) + {R}_{0} ( t , {I}_{t} , {T}_{t} , {\hat{c}}_{t} ) {I}_{t} + {ϵ}_{t} , {ϵ}_{t} ∼ N ( 0 , {σ}_{n}^{2} ) \qquad [ eqn : regression ]$$

where Vₜ is the terminal voltage and t, Iₜ, Tₜ, ĉₜ are the (normalised) time since beginning of life, applied current, measured temperature and estimated bulk sulfuric acid concentration at time t respectively. Voc is the experimentally obtained open circuit voltage function and the dependency R₀(Iₜ, Tₜ, ĉₜ, t) is modelled by a zero mean Gaussian Process, so that

$${R}_{0} ( x ) ∼ 𝒢𝒫 ( 0 , k ( x ) ) , x ∈ \{ t , I , T , \hat{c} \}$$

where k is the covariance function.

In this example, the first kernel and the second non-stationary kernel are combined by addition. By modelling R₀ as a sum of two GPs, where the degradation process over the temporal domain is described by the Wiener velocity (WV) kernel [8] and the dependencies on operating point (Iₜ, Tₜ, ĉₜ) by the squared exponential (SE) kernel, such that

$$k ( I , T , \hat{c} , t ) = {σ}_{f , 0}^{2} ( \frac{{min}^{3} ( t , {t}^{′} )}{3} + \vert t - {t}^{′} \vert \frac{{min}^{2} ( t , {t}^{′} )}{2} ) + {σ}_{f , 1}^{2} exp ( {\sum }_{x ∈ \{ I , T , \hat{c} \}} - \frac{{( x - {x}^{′} )}^{2}}{2 {l}_{x}^{2}} ) \qquad [ eqn : kernel ]$$

where |·| denotes the absolute distance between two points. The choice of the WV process, used in target tracking applications allows for better extrapolation outside the observed data as the kernel is non-stationary. In comparison, using the zero-mean SE kernel results in extrapolation over longer time horizons to tend to the prior distribution. The prior distributions over functions for the two types of kernel is shown in FIG. 6, which shows random draws from each kernel.

The extrapolation over time is used in this case, as the sampling points are relatively sparse and the down-sampled data is not evenly distributed over time across the population. Extrapolation is thus required to give estimates of R₀ at points preceding the data series end for each battery 2. Additionally, expressing R₀ as a sum of kernels ([eqn:kernel]) makes the assumption that the degradation is purely additive and independent of the operating point chosen. This significant simplification reduces the degrees of freedom of the system in comparison to a product of kernels over all inputs and makes inference computationally lower cost.

In the regression defined by ([eqn:normalize]-[eqn:kernel]), the hyperparameters to be estimated are the two process variances oro, Of, and length scales lₓ across the inputs, (Iₜ, Tₜ, ĉₜ). The measurement noise variance on encompasses uncertainty from not only the model error in GP regression, but measurement error in terminal voltage and the open-circuit voltage, which is estimated. Due to the open-loop Coulomb counting method, the system is heteroskedastic, with σₙ² calculated as

$${σ}_{n}^{2} = 0.05 + Var ( \hat{c} ) {( \frac{{dV}_{OC}}{dc} {\vert}_{\hat{c}} )}^{2} \qquad [ eqn : Coulomb\_counting ]$$

where the variance of c\hat{ } is the cumulative variance from Coulomb counting assuming a σ=10% error in equation ([eqn:Coulomb_counting]).

In order to impose smoothness of the function R₀ over all input dimensions, a prior distribution over hyperparameters may be used such that

$$p ( {σ}_{f , 0} , {σ}_{f , 1} , {l}_{T} , {l}_{I} , {l}_{\hat{c}} ) = {\prod }_{m ∈ \{ 0 , 1 \}} χ ( {σ}_{f , m} , k = 1 , s = 0.2 ) {\prod }_{x ∈ \{ I , T , \hat{c} \}} {Γ}^{- 1} ( {l}_{x} , α = 1 , β = 2 ) ,$$

where χ represents the chi distribution and Γ⁽⁻¹⁾ the inverse gamma distribution. The chi distribution with the degree of freedom k=1 is equal to a half-normal distribution with standard deviation s=0.2. By using the inverse length scale in the prior, an inverse gamma prior is provided for the length scales with shape and scale parameters α and β chosen to give a mode of 1.

In order to estimate the posterior distribution of R₀ for each battery and to recover maximum-a-posteriori (MAP) estimates of the hyperparameters, a recursive estimation framework for GPs [5], [11], [4], resulting from the interpretation of the process as the solution of a stochastic partial differential equation of the form

$$\frac{\partial {R}_{0} ( t , I , T , \hat{c} )}{\partial t} = {FR}_{0} ( t , I , T , \hat{c} ) + Lw ( t , I , T , \hat{c} ) \qquad [ eqn : GP\_SDE ]$$

This framework allows the use of the standard Kalman filtering and smoothing techniques [8] to be used to estimate both the posterior distribution of R₀ and the so-called energy function, that is the negative unnormalized logarithm of the posterior probability of the hyperparameter vector. Crucially, this method scales as [symbol] (n) over the number of charging segments, which in our case is of the order of 10⁴ for each battery.

To obtain a finite-dimensional representation of the system ([eqn:GP_SDE]), a similar approach may be used to that of Särkkä et al. [4]. First, the k-means algorithm is applied to choose a predetermined number (e.g. 20 in the First Example) of representative points across (Iₜ, Tₜ, ĉₜ), for which R₀ through the lifetime of the battery 22 is estimated. In order to obtain estimates for R₀ for the observed (Iₜ, Tₜ, ĉₜ) through charging segments, the predictive distribution of the GP over operating points is calculated and added to the value predicted by the degradation GP.

To achieve linear computational scaling over data rows n when estimating the posterior distribution of R₀ for each battery 2, the recursive framework pioneered by Särkkä et al. [4], [5] may be applied. In this formulation, the posterior of R₀ and the so-called energy function, that is the negative logarithm of the unnormalized posterior probability of the hyperparameters, may be obtained by employing standard Kalman filtering and smoothing techniques. As previously mentioned, the kernel function is represented by

$$k ( I , T , \hat{c} , t ) = {σ}_{f , 0}^{2} ( \frac{{min}^{3} ( t , {t}^{′} )}{3} + \vert t - {t}^{′} \vert \frac{{min}^{2} ( t , {t}^{′} )}{2} ) + {σ}_{f , 1}^{2} exp ( {\sum }_{x ∈ \{ I , T , \hat{c} \}} - \frac{{( x - {x}^{′} )}^{2}}{2 {l}_{x}^{2}} ) \qquad [ eqn : kernel ]$$

as a linear dynamic system of the type

$$\frac{\partial {R}_{0} ( t , I , T , \hat{c} )}{\partial t} = {FR}_{0} ( t , I , T , \hat{c} ) + Lw ( t , I , T , \hat{c} ) \qquad [ eqn : kernel ]$$

Following the methods outlined in [13], this system is represented in discrete time by the propagation of the mean and covariance of the GP over time by the standard Kalman Filter equations where the prior predictive mean and covariance are given by

$${z}_{t}^{-} = {A}_{GP} {z}_{t - 1}^{+} \qquad [ eqn : KF\_prop ]$$

$${P}_{t}^{-} = {A}_{GP} {P}_{t - 1}^{+} {A}_{GP}^{T} + {Q}_{GP}$$

The additive kernel (Legn:kernell) gives a block diagonal system where the state vector is a concatenation of the two processes,

$$z = {[ {z}_{GP , 0} {z}_{GP , 1} ]}^{T} ,$$

where z_{GP,0} represents the degradation GP and consists of the vector [Rₜ, ∂Rₜ/∂t]^{T} and z_{GP,1} represents the mean of the GP over the operating point which is constant over time. While the system ([eqn:kernel]) is infinite-dimensional, a finite dimensional representation over the operating points is applied by choosing 20 inducing points over (I,T,c\hat{ }) for each battery using k-means, making z_{GP,1}∈ [symbol] ²0. Given the state vector, the discrete time transition matrix A_{GP} is block diagonal,

$${A}_{GP} = exp m ( [ \begin{matrix}{F}_{GP , 0} & 0 \\ 0 & {F}_{GP , 1}\end{matrix} ] Δ t ) , where {F}_{GP , 0} = [ \begin{matrix}0 & 1 \\ 0 & 0\end{matrix} ] , {F}_{GP , 1} = 0 ,$$

where 0 indicates a square matrix of zeros of size 20 and Δt denotes the time-step between charging segments. The process covariance Q_{GP} is also block-diagonal, given by

$${Q}_{GP} = [ \begin{matrix}{Q}_{GP , 0} & 0 \\ 0 & {Q}_{GP , 1}\end{matrix} ] , where {Q}_{GP , 0} = [ \begin{matrix}\frac{1}{3} Δ {t}^{3} & \frac{1}{2} Δ {t}^{2} \\ \frac{1}{2} Δ {t}^{2} & Δ t\end{matrix} ] , {Q}_{GP , 1} = 0$$

As a zero-mean GP is used, the state vector z_{GP} is initialized at zero. The covariance matrix for the dynamic system is likewise block-diagonal,

$${P}_{GP} = [ \begin{matrix}{P}_{GP , 0} & 0 \\ 0 & {P}_{GP , 1}\end{matrix} ]$$

initialised separately for the two subsystems. The integrated Wiener process is defined to have zero initial covariance, so that P_{GP,0}=0. For the second GP over operating points, which has no time dependency, the initial covariance is given by P_{GP,1}=σ_{f,1}²I, where I is the identity matrix of dimensionality 20 due to the number of inducing points chosen.

Given the propagation, the observation model contains the GP describing the dependency on operating point. This means that the estimated internal resistance at any point in time is expressed as a linear combination of the state vector, such that the observation model for voltage was given

$${V}_{t} ∼ 𝒩 ( {V}_{OCV} ( {\hat{c}}_{t} ) + {H}_{t} {z}_{GP , t} , {σ}_{r , t}^{2} )$$

where the matrix Hₜ∈ [symbol] ^{(n*22)}, n being the number of data points in the charging segment and

$${H}_{t} = [ \begin{matrix}{H}_{0} & {H}_{1}\end{matrix} ] = {I}_{t} [ \begin{matrix}1 & 0 & {k ( {x}_{t} , {X}_{u} ) [ k ( {X}_{u} , {X}_{u} ) + {P}_{GP , 1 , t}^{-} ]}^{- 1} \\ ⋮ & ⋮ & ⋮\end{matrix} ]$$

where k(·) is the SE kernel covariance function in ([eqn:kernel]), xₜ=[(Iₜ Tₜ ĉₜ] and Xᵤ∈ [symbol] ^{(20*30)} the location of the inducing points in terms of (It Tt ct). We add the prior state covariance matrix estimate P_{GP,1,t}⁻ to k(Xᵤ, Xᵤ) in ([eqn:obs_model]) to reflect the uncertainty in the states as they are propagated through time. The uncertainty around the points can vary significantly due to the observed (Iₜ, Tₜ, ĉₜ) changing from one segment to the next. The variance in the observation model is given by

$${σ}_{r , t}^{2} = diag [ k ( {x}_{t} , {x}_{t} ) - {k ( {x}_{t} , {X}_{u} ) [ k ( {X}_{u} , {X}_{u} ) + {P}_{GP , 1 , t}^{-} ]}^{( - 1 )} k ( {X}_{u} , {x}_{t} ) ] + I {σ}_{n , t}^{2} ,$$

where the calculation of ont is described above. The linear system ([eqn:KF_prop]-[eqn:obs_var]) was used in the standard forward Kalman filtering equations, to which we added the recursive calculation of the so-called energy function, that is the unnormalised negative logarithm of the posterior probability of the hyperparameter vector,

$$Φ ( {θ}_{h} ) = - log p ( {θ}_{h} ) + 1 / 2 {\sum }_{t} log \vert 2 π {S}_{t} ( {θ}_{h} ) \vert + 1 / 2 {\sum }_{t} {e}_{t}^{T} {{S}_{t} ( {θ}_{h} )}^{( - 1 )} {e}_{t} ,$$

where p(θₕ) is the hyperprior specified above, et the error vector for each charging segment, and Sₜ(θₕ) the innovation covariance for the segment. This gives a pointwise estimate of the parameter posterior probability for each pass through the data. This is used in calculating MAP estimates of θₕ=[σ_{f,0} σ_{f,1} lₓ], by using the L-BFGS-B algorithm implemented in SciPy. To improve efficiency, the jacobian of the energy function may be determined analytically by extending the recursive method outlined by Mbalawata et al. to include terms for the observation model ([eqn:obs_model]-[eqn:obs_var]).

Differentiating the energy function with respect to θₕ and dropping the dependency on θₕ in notation for convenience produces

$$\frac{\partial Φ}{\partial {θ}_{h}} = - \frac{\partial log p ( {θ}_{h} )}{\partial {θ}_{h}} + \frac{1}{2} {\sum }_{n} Tr ( {S}_{t}^{- 1} \frac{\partial {S}_{t}}{\partial {θ}_{h}} ) - \frac{1}{2} {\sum }_{n} {( {H}_{t} \frac{\partial {z}_{t}^{-}}{\partial {θ}_{h}} + \frac{\partial {H}_{t}}{\partial {θ}_{h}} {z}_{t}^{-} )}^{T} {S}_{t}^{- 1} {e}_{t} - \frac{1}{2} {\sum }_{n} {e}_{t}^{T} {S}_{t}^{- 1} \frac{\partial {S}_{t}}{\partial {θ}_{h}} {S}_{t}^{- 1} - \frac{1}{2} {\sum }_{n} {e}_{t}^{T} {S}_{t}^{- 1} ( {H}_{t} \frac{\partial {z}_{t}^{-}}{\partial {θ}_{h}} + \frac{\partial {H}_{t}}{\partial {θ}_{h}} {z}_{t}^{-} ) ,$$

where Tr denotes the matrix trace and

$$\frac{\partial {S}_{t}}{\partial {θ}_{h}} = \frac{\partial {H}_{t}}{\partial {θ}_{h}} {P}_{t}^{-} {H}_{t}^{T} + {H}_{t} \frac{\partial {P}_{t}^{-}}{\partial {θ}_{h}} {H}_{t}^{T} + {H}_{t} {{P}_{t}^{-} ( \frac{\partial {H}_{t}}{\partial {θ}_{h}} )}^{T} + \frac{\partial {σ}_{r , t}^{2}}{\partial {θ}_{h}} .$$

Given the relations ([eqn:dpsidtheta])-([eqn:dsdtheta]), the standard Kalman filter states can be augmented with their partial derivatives with respect to the hyperparameters,

$$\frac{\partial {z}_{t}}{\partial {θ}_{h}} , \frac{\partial {P}_{t}^{-}}{\partial {θ}_{h}} ,$$

and propagated as described by Mbalawata et al. [14]. While using the matrix fraction decomposition for the augmented covariance propagation [14] can be slow due to the large matrix exponential calculation required, the structure of the covariance function ([eqn:kernel]) with process transition matrices ([eqn:Fmats]) in the state space representation allow for a closed form solution which can be evaluated at a fraction of the computational cost. As a result, the dominant cost in the Kalman filter recursion becomes the inversion of the innovation covariance, Sₜ, which is already incorporated in the standard recursion. The full posterior predictive distributions 12 of R₀ for each battery 2, given the hyperparameters 13, is then obtained by using the RTS smoother [15] given the forward pass.

Thus, the output of the GP regression in step S2 is a fitted model represented by the posterior predictive distributions 12 of internal resistance and a posterior estimate of the hyperparameters 13. In the First Example, these methods enabled fitting of hyperparameters in approximately 90 minutes across the entire population of batteries, consisting of 16 million rows of data, using an Apache Spark cluster with 15 cores running on an Intel Xeon 4216 CPU physical processor at 2.1 GHZ and 20 GB RAM allocation.

In the First Example, the MAP estimates of the hyperparameters 13 for kernel function ([eqn:kernel]) retrieved for each of the datasets where data was cut off at 0, 2, 4, 6 and 8 weeks before the end of each time series separately for each battery 2 in our dataset using a parallel approach. FIG. 8 shows the distribution of the hyperparameters and the values median MAP estimates of the hyperparameters retrieved in each case are shown in the following table:

| Weeks | | | | | |
|---|---|---|---|---|---|
| before | l_{T} | l_{I} | l\hat{_{c}} | σ_{(f, 0)} | σ_{(f, 1)} |
| 0 | 3.51 | 1.70 | 2.78 | 0.96 | 0.31 |
| 14 | 3.72 | 1.71 | 2.80 | 0.94 | 0.31 |
| 28 | 3.79 | 1.71 | 2.83 | 0.89 | 0.31 |
| 42 | 3.72 | 1.70 | 2.86 | 0.89 | 0.31 |
| 56 | 3.70 | 1.71 | 2.86 | 0.83 | 0.31 |

As mentioned above, the hyperparameters 13 may be specific to each battery 2 or may be common to all the batteries 2.

If the hyperparameters 13 are specific to each battery 2, then the respective hyperparameters 13 may be fitted over the sensor data 10 of respective batteries 2 in the set. This option may improve the fitting and was performed in the First Example.

If the hyperparameters 13 are common to all batteries 2, the hyperparameters 13 may be fitted over the sensor data 10 of all the batteries 2 in the set in step S2, or may have predetermined values, for example having been previously derived from a training data set that is representative of the population of batteries 2. Use of hyperparameters that are specific to each battery 2 may improve the performance of the health metric when used as input variables in a classification process, for example as described further below.

Next, there will be described an example of step S2 suitable for batteries 2 that are lithium-ion batteries (or more generally lithium-ion electrochemical energy supply elements).

In this example, the health parameter is capacity, because this is often of more interest than internal resistance when dealing with lithium-ion systems. Charge rates and discharge rates may be higher than the rates for the simple lead acid model used above. To address this, in this example the Gaussian model incorporates a more complex circuit model of the battery 2 coupled with a simple thermal model, as shown in FIG. 9. The circuit model models the battery 2 in accordance with Ohm's law as having a capacitive reactance in parallel with part of the internal resistance. In general, in any embodiment of the present invention, the Gaussian Process may use such a circuit model of the battery.

The thermal model is a single state model for the temperature of the battery, which is assumed uniform across it. Heat is generated mainly through ohmic heating and dissipated by Newtonian cooling into the environment. The thermal model is optional, but is helpful if the temperature range in the given application is substantial. The (coupled) system allows for more accurate modelling under higher rates. This may be used to simultaneously estimate internal resistance, capacity and other model parameters.

Additionally, whereas the First Example took the state of charge (zt) as a given, the Second Example estimates it at the same time as the model parameters, making the new approach more applicable to online applications. This is particularly useful where the state of charge estimate is not readily available, or the available estimate is not accurate. Applying the algorithm in an online manner means that it can conceivably be run by on-board computers in an electric vehicle, for example.

The continuous-time dynamics of the electro-thermal model shown schematically in FIG. 9 are given by

$$\frac{{dz}_{t}}{dt} = {I}_{t} {Q}^{- 1} ( {ζ}_{t} )$$

$$\frac{{dV}_{1 , t}}{dt} = - α ( {z}_{t} , {ζ}_{t} ) {V}_{1 , t} + β ( {z}_{t} , {ζ}_{t} ) {I}_{t}$$

$$\frac{{dT}_{c , t}}{dt} {C}_{c} = - \frac{{T}_{c , t} - {T}_{amb , t}}{{R}_{c}} + ( {V}_{t} - {V}_{0} ( {z}_{t} ) ) {I}_{t} ,$$

where zₜ is the state of charge, Iₜ the applied current and Q⁻¹(ζₜ ) the inverse battery capacity as a function of battery lifetime ζₜ. Battery lifetime ζₜ may be measured either by calendar age or total Ampere-hour throughput over lifetime. V_{l,t} is the voltage across the RC-pair, and its time dynamics are controlled by the functions α(zₜ, ζₜ) and β(zₜ, ζₜ). The functions α(·) and β(·) may be related back to the circuit parameters, as α=1/R₁C₁ and β=1/C₁. For the thermal model it is assumed that temperature is uniform across the cell, which is parameterised by its heat capacity C_{c} and thermal resistance R_{c}. Given the dynamics, the outputs are cell temperature Tₜ and the terminal voltage, given by

$${V}_{t} = {V}_{0} ( {z}_{t} ) + {V}_{1 , t} + {R}_{0} ( {z}_{t} , {I}_{t} , {ζ}_{t} ) {I}_{t}$$

$${T}_{t} = {T}_{c , t}$$

It should be noted that the model can be extended to include temperature dependencies for the circuit elements, but as the input data used here only has a temperature range of approximately 5° C., this was not necessary. The four functions Q⁻¹(ζₜ), α(zₜ, ζₜ), β(zₜ, ζₜ) and R₀(zₜ, Iₜ, ζₜ) are all assumed to be affine transformations of independent zero-mean Gaussian processes, so that

$$f ∼ {t}_{f} ( 𝒢𝒫 ( 0 , {k}_{f} ( x , {x}^{′} ) ) ) , x ∈ [ {z}_{t} , {I}_{t} , {ζ}_{t} ] , f ∈ [ {Q}^{- 1} , α , β , {R}_{0} ] .$$

The affine transformation in each case is

$${t}_{f} ( x ) = {c}_{f} ( 1 + x ) ,$$

where c_{f} is a constant. As a Gaussian distribution remains Gaussian under arbitrary affine transformations, the four functions are also Gaussian processes. The reason for the transformation to improve the numerical stability of the system dynamics.

In general, the kernel function k is constructed so that the time input (ζₜ) is treated differently from the inputs consisting of the instantaneous operating conditions (zₜ and Iₜ). In this case, a non-stationary kernel function describes each of the four Gaussian processes in the time dimension, which allows for better extrapolation than a stationary kernel which reverts back to the mean upon long-range extrapolation. The non-stationary kernel is the Wiener velocity kernel, given by

$$k ( ζ , {ζ}^{′} ) = {σ}^{2} ( \frac{{min}^{3} ( ζ , {ζ}^{′} )}{3} + \vert ζ - {ζ}^{′} \vert \frac{{min}^{2} ( ζ , {ζ}^{′} )}{2} ) .$$

The kernel describing the process over state of charge zₜ and applied current Iₜ is the rational quadratic kernel,

$$k ( x , {x}^{′} ) = {{σ}^{2} ( 1 + \frac{{\vert x - {x}^{′} \vert}^{2}}{2 α {l}^{2}} )}^{- α} ,$$

which has the property of effectively ‘mixing’ a multitude of length scales over the input, giving it more flexibility that the Matérn family of kernels. The factor controlling the weight of the length scale is α. Combining the kernels [eqn:nonstat-kernel] and [eqn:stat_kernel] may be done in two different ways, by either multiplying the two functions or by adding them,

$$k ( x , {x}^{′} ) = \{ \begin{matrix}k ( ζ , {ζ}^{′} ) {\prod }_{x ∈ [ z , I ]} k ( x , {x}^{′} ) & ( multiplicative ) \\ k ( ζ , {ζ}^{′} ) + {\prod }_{x ∈ [ z , I ]} k ( x , {x}^{′} ) & ( additive )\end{matrix} ,$$

where both formulations are valid kernel functions. The choice between the two formulations depends on whether the degradation process can be considered to affect the battery dynamics equally across the operating conditions. If the degradation process over time is such that it affects battery parameters equally across the range of operating conditions, the additive formulation is a better choice as it is often computationally more efficient. If however, different points in over the range of operating points experience significantly varying behaviour over degradation, a multiplicative kernel is more appropriate. The kernel function over instantaneous operating points is always multiplicative to keep flexibility and this does not incur a computational penalty.

To fit the GP to observed data given the choice of kernel function ([eqn:add_mult_k]), a computationally efficient solution to find the GP hyperparameters and posterior distributions is applied. This is formulated as a recursive state-parameter estimator consisting of a joint extended Kalman filter (jEKF). In previous work it has been shown that Gaussian processes are solutions to linear stochastic (partial) differential equations. Due to this property, it is possible to construct a linear dynamic system from a GP with kernel function k that has the form of a stochastic process

$$\frac{\partial f ( x , t )}{\partial t} = Ff ( x , t ) + Lw ( x , t ) ,$$

where f (x, t) is a Gaussian process, F the transition matrix,L the dispersion matrix and w(x, t) spatially resolved white noise. The equivalence between the GP kernel and the dynamic system means that there is a mapping between matrices F,L and w(x, t) and the kernel function hyperparameters. Both the additive and multiplicative kernels can be used to construct these matrices. In general, degradation is more accurately represented by a GP with a non-stationary kernel, such as a polynomial or integrated Wiener process. The Wiener velocity kernel, for example, given by

$${σ}^{2} ( \frac{{min}^{3} ( t , {t}^{′} )}{3} + \vert t - {t}^{′} \vert \frac{{min}^{2} ( t , {t}^{′} )}{2} ) ,$$

has a dynamic representation whereby

$${F}_{WV} = [ \begin{matrix}0 & 1 \\ 0 & 0\end{matrix} ] , {L}_{WV} = [ \begin{matrix}0 \\ 1\end{matrix} ] ,$$

and the spectral density of noise w(t) is given by σ².

In the following, it is described how the GP posterior distributions and hyperparameters may be retrieved jointly with battery states using a recursive formulation.

Let the vector X_{Batt,t} denote the battery states at time t,

$${X}_{Batt , t} = [ \begin{matrix}{z}_{t} & {V}_{1 , t} & {{T}_{c , t} ]}^{T} ,\end{matrix}$$

and the vector X_{GP,t} denote the state vector associated with each of the GPs describing the model parameters, so that

$${X}_{GP , t} = {[ \begin{matrix}{x}_{{Q}^{- 1} , t} & {x}_{α , t} & {x}_{β , t} & {x}_{{R}_{0} , t}\end{matrix} ]}^{T} ,$$

where each GP has its own state vector x_{.,t}. The dimensionality of the state vector depends on two factors. Firstly, if an additive process of the two GPs is used,

$${x}_{f , t} = {[ {x}_{f , 0 , t} {x}_{f , 1 , t} ]}^{T} , f ∈ \{ {Q}^{- 1} , α , β , {R}_{0} \} ,$$

that is the state vector is a concatenation of the operating point GP and the temporal GP. The dimensionality of the temporal subcomponent is only determined by the type of non-stationary kernel chosen, where x_{f,1,t}∈ [symbol] ² for the WV kernel. The number of states in the ‘operating point’ subcomponent depends on the spatial discretisation applied in each case—for the function describing (inverse) capacity, Q⁻¹(ζₜ), there is no dependency on either zₜ or Iₜ, so the state vector x_{Q}_{^{−1}}_{,0,t} is in fact scalar. For x_{α,t}, x_{β,t}, dimensionality is determined by the number of points over zₜ chosen to describe the process, so that x_{α,t}, x_{β,t}∈ [symbol] ^{D}^{_{z}}⁺², where D_{z} is the number of ‘SoC points’ used. Similarly for function R₀(Zy It), where the two-dimensional inputs requires a larger number of points to cover the input space, x_{R}_{₀}_{,0,t}∈ [symbol] ^{D}^{_{z,I}}, where D_{z,I} is the number of points in the space z, I used.

The multiplicative case is simpler but tends to have higher dimensionality. All processes are ‘lumped’ together without separating the states, which gives x_{α,t}, x_{β,t}∈ [symbol] ^{D}^{_{z}}^{*2}. Similarly for function R₀(zₜ, Iₜ), where xR₀, t∈ [symbol] ^{D}^{_{z,I}}⁺². The overall state-space system representation is then given by the concatenation of the two vectors,

$${X}_{t} = [ \begin{matrix}{X}_{Batt , t} \\ {X}_{GP , t}\end{matrix} ] .$$

The system is propagated over time using the standard extended Kalman filter recursion, which consists of the mean and covariance of each state in the system. where Xₜ is the mean vector and Pₜ is covariance matrix which is block-diagonal,

$${P}_{t} = [ \begin{matrix}{P}_{Batt , t} & 0 \\ 0 & {P}_{GP , t}\end{matrix} ] , {P}_{GP , t} = [ \begin{matrix}{P}_{Q , t} & 0 & 0 & 0 \\ 0 & {P}_{α , t} & 0 & 0 \\ 0 & 0 & {P}_{β , t} & 0 \\ 0 & 0 & 0 & {P}_{{R}_{0} , t} ,\end{matrix} ]$$

where dimensionality of is given by

$${P}_{t} ∈ \{ \begin{matrix}{ℝ}^{11 + 2 {D}_{z} + {D}_{z , I} * 11 + 2 {D}_{z} + {D}_{z , I}} , & additive case \\ {ℝ}^{3 + 4 {D}_{z} + 2 {D}_{z , I} * 3 + 4 {D}_{z} + 2 {D}_{z , I}} , & multiplicative case\end{matrix} .$$

The joint system functions at two distinct timescales. The first timescale is during operation, where battery states change according to the system dynamics ([eqn:batt_dyn]). Over this time-scale (within a single charge/discharge cycle), the degradation dynamics described by the non-stationary (WV) kernel may be considered slow, which allows for the linearisation of the system dynamics and a simpler discrete-time solution. Between charge/discharge cycles on the other hand, only the GP has non-zero dynamics.

The initialisation of the subsystem describing battery dynamics is best done at rest, whereby the states maybe recovered easily as V_{1,t}≈0 and the output equations ([eqn:outputs]) are easily inverted. Whereas battery states have to be re-initialised at the start of every charge/discharge cycle, the GP states only have to be initialised at the beginning of life for the battery. The initialisation depends again on whether the multiplicative or additive GP formulation is used. For the additive case,

$${P}_{0 , f} = [ \begin{matrix}{σ}_{f}^{2} I & 0 \\ 0 & 0 ,\end{matrix} ]$$

where σ_{f}² is the hyperparameter describing the magnitude of the GP over the instantaneous operating points described by the stationary kernel ([eqn:stat_kernel]) for each of the four functions f. For the multiplicative case,

$${P}_{0 , f} = {k}_{f} ( x , {x}^{′} ) ⊗ {F}_{WV} , x ∈ [ z , I ]$$

where ⊗ denotes the Kronecker product. It should be noted that initialising the multiplicative case effectively relies on transforming the timescale ζ to start at a non-zero value—the multiplicative kernel can not have zero variance at the beginning of life.

Given the initialisation and separation of the timescales, the system is propagated forward in discrete time by

$${X}_{t + 1} = g ( {X}_{t} , {I}_{t} )$$

$${P}_{t + 1} = {G}_{t} {P}_{t} {G}_{t}^{T} + {Q}_{t} + {λ}_{t} ,$$

where g describes the system-dynamics, Gₜ is the Jacobian matrix of g w.r.t. Xₜ, Qₜ the joint discrete time process covariance and λₜ a corrective term arising from the posterior predictive term of the GP (see below). The instantaneous values of the GP functions α, β, R₀ with dependency on zₜ and/or Iₜ and the time input are determined by the predictive distribution of each GP, where the means and variances of multiplicative and additive cases are given by

$${μ}_{f} ( {z}_{t} , {I}_{t} ) = {{k}_{f} ( [ {z}_{t} {I}_{t} ] , {U}_{f} ) [ {k}_{f} ( {U}_{f} , {U}_{f} ) + diag ( {P}_{f , t} ) ]}^{- 1} {x}_{f , t}$$

$${𝕍}_{f} ( {z}_{t} , {I}_{t} ) = {k}_{f} ( [ {z}_{t} {I}_{t} ] , [ {z}_{t} {I}_{t} ] ) - {{k}_{f} ( [ {z}_{t} {I}_{t} ] , {U}_{f} ) [ {k}_{f} ( {U}_{f} , {U}_{f} ) + diag ( {P}_{f , t} ) ]}^{- 1} {k}_{f} ( {U}_{f} , [ {z}_{t} {I}_{t} ] )$$

in the multiplicative case and

$${μ}_{f} ( {z}_{t} , {I}_{t} ) = {{k}_{f} ( [ {z}_{t} {I}_{t} ] , {U}_{f} ) [ {k}_{f} ( {U}_{f} , {U}_{f} ) + diag ( {P}_{f , 0 , t} ) ]}^{- 1} {x}_{f , 0 , t} + {x}_{f , 1 , t}$$

$${𝕍}_{f} ( {z}_{t} , {I}_{t} ) = {k}_{f} ( [ {z}_{t} {I}_{t} ] , [ {z}_{t} {I}_{t} ] ) - {{k}_{f} ( [ {z}_{t} {I}_{t} ] , {U}_{f} ) [ {k}_{f} ( {U}_{f} , {U}_{f} ) + diag ( {P}_{f , t} ) ]}^{- 1} {k}_{f} ( {U}_{f} , [ {z}_{t} {I}_{t} ] ) + {P}_{f , 0 , t}$$

sin the additive case, where kₜ is the stationary kernel for function f and U_{f} denotes the vector of points for spatial discretisation across the inputs.

The discrete time process noise covariance matrix Qₜ is block-diagonal, where by the values for the battery states are fixed and the values for the GP are determined by the kernel function hyperparameters. More specifically, the WV kernel has a discrete time process variance given as a function of the time-step in ζ and the spectral density of the temporal

$${Q}_{WV} ( Δ ζ ) = {σ}_{f , 1}^{2} [ \begin{matrix}\frac{1}{3} Δ {ζ}^{3} & \frac{1}{2} Δ {ζ}^{2} \\ \frac{1}{2} Δ {ζ}^{2} & Δ ζ\end{matrix} ] ,$$

which again combines with the spatial covariance in a manner depending on whether an additive of multiplicative system is used, giving

$${Q}_{t} = [ \begin{matrix}{Q}_{Batt} & 0 \\ 0 & {Q}_{GP}\end{matrix} ] , where {Q}_{Batt} = [ \begin{matrix}{q}_{z} & 0 & 0 \\ 0 & {q}_{{V}_{1}} & 0 \\ 0 & 0 & {q}_{{T}_{c}}\end{matrix} ] ,$$

and the GP subcomponent is

$${Q}_{GP} = [ \begin{matrix}0 & 0 \\ 0 & {I}_{4} ⊗ {Q}_{WV , f}\end{matrix} ]$$

in the additive case, where I₄ denotes the identity matrix size 4 and

$${Q}_{GP} = \text{} [ \text{} \begin{matrix}{Q}_{WV , {Q}^{- 1}} & 0 & 0 & 0 \\ 0 & \begin{matrix}{k}_{α} ( {U}_{α} , {U}_{α} ) ⊗ \\ {Q}_{WV , α}\end{matrix} & 0 & 0 \\ 0 & 0 & {k}_{β} ( {U}_{β} , {U}_{β} ) ⊗ {Q}_{WV , β} & 0 \\ 0 & 0 & 0 & \begin{matrix}{k}_{{R}_{0}} ( {U}_{β} , {U}_{β} ) ⊗ \\ {Q}_{WV , {R}_{0}}\end{matrix}\end{matrix} ] \text{}$$

in the multiplicative case.

The corrective term in covariance propagation equation is due to 2 factors—as α, β, R₀ are finite dimensional representations of the GP, the point values predicted in for the purposes of the state dynamics have an extra variance due to interpolation/extrapolation between the discrete points U_{f} in each case. In addition, the posterior predictive distribution uses as an input zₜ, which is itself a random Gaussian variable which needs to be marginalised over. λₜ thus contains 2 non-zero elements along the diagonal to approximate these two additional variances which pertain to the dynamics dV_{1,t}/dt and dT_{c,t}/dt.

Given the predictive mean and covariance from eqns. ([egn:KF_prop]), predicted terminal voltage is given by h(Xₜ, Iₜ), given in equation ([eqn:outputs]). To complete the Kalman filter recursion, the standard relations are used (with Joseph form covariance update):

$${e}_{t} = [ {V}_{t} {T}_{t} ] - h ( {X}_{t} , {I}_{t} )$$

$${S}_{t} = {H}_{t} {P}_{t}^{-} {H}_{t}^{T} + R$$

$${K}_{t} = {P}_{t}^{-} {H}_{t}^{T} {S}_{t}^{- 1}$$

$${X}_{t}^{+} = {X}_{t}^{-} + {K}_{t} {e}_{t} \begin{matrix} & ,\end{matrix}$$

$${P}_{t}^{+} = {( I - {K}_{t} {H}_{t} )}^{T} {P}_{t}^{-} ( I - {K}_{t} {H}_{t} ) + {K}_{t} {RK}_{t}^{T}$$

$${Φ}_{t} = {Φ}_{t} + \frac{1}{2} {e}_{t}^{T} {S}_{t}^{- 1} {e}_{t} + \frac{1}{2} log \vert 2 {π S}_{t} \vert$$

where Hₜ is the jacobian of h(·) and Ωₜ is the recursively updated energy function over the observed data, which can be used to fit all hyperparameters.

The total number of hyperparameters for the system is 12, including all length scales, magnitudes and the diagonal elements of the measurement noise R.

To speed up the optimisation of hyperparameters, the input-output data may be used sampled more efficiently. For all length scales and magnitudes involving inputs over the operating points as well as the measurement noises, only 1 (full) discharge cycle is required. The dimensionality of the hyperparameters over time maybe reduced to 2, meaning that the full dataset (over which it is slower to iterate) only has be used to optimise 2 hyperparameters instead of the original 12.

In step S3, health metrics 14 over time are derived for respective batteries 2 using the fitted model. In particular, the health metrics 14 are values of the health parameter that are predicted by the fitted model in respect of a predetermined operating point of the operational parameters.

As discussed further below, the values of the health metric used in FIG. 1 comprise absolute values of the health parameter and partial derivatives of the health parameter with respect to time. More generally, the values could include only the absolute values or only the derivatives. Alternatively, the values could also include higher order derivatives. The choice of the time derivative, instead or as well as the absolute value of resistance, may be used to reflect the expected ‘knee-point’ in battery degradation, that is the onset of accelerated degradation towards end-of-life. As the recursive method chosen to calculate the posterior distributions of R₀ for each battery 2 already calculate this partial derivative, no extra calculation is required.

Specifically, the posterior predictive distributions 12 of internal resistance for each battery 2 can then be used to extrapolate the value of R₀ to any given operating point by using the extrapolation

$${R}_{0} ( x ) = {k ( x , {X}_{u} ) [ k ( {X}_{u} , {X}_{u} ) + {P}_{GP , 1}^{s} ]}^{- 1} {z}_{GP , 1}^{s} ,$$

where z_{GP,1}^{s} and P_{GP,1}^{s} denote the RTS smoothed mean and covariances, which are constant in time for the GP over the operating point. For the degradation process, the value of z_{GP,0} and P_{GP,0} could be obtained by applying the forward propagating equations (Legm. KE prop) using as a starting point the RTS smoothed values.

A similar method may be used for benchmarking the approach, but as R₀ is considered independent of the operating point and modelled by a random walk through time, the state vector zₜ, variance Pₜ as well as the process variance Q become scalar and transition matrix A is simply 1. It is assumed to be independent of operating conditions. The vector valued observations are the same and the measurement error consists solely of Iσᵣ². The hyperparameters, estimated by maximum likelihood using the same recursion as the main method, consist of the process and noise variances, Q and σᵣ² respectively. The initial variance of the state vector was set to 10Q in each case. This process is also controlled by a set of hyperparameters for which we found maximum-likelihood estimates using the same methodology.

The following was carried out in the First Example.

The health metrics 13 that are absolute values of internal resistance derived the First Example are shown schematically in FIG. 3(c).

Internal resistance of a battery 2 is a useful indicator of state of health, however it depends not only on degradation, but also on instantaneous temperature, current and state of charge. FIG. 10 top row shows the considerable variation in temperature, current and state of charge experienced by the batteries 2 across the down-sampled dataset. In lab tests, these conditions can be tightly controlled to ensure consistent estimates of health, but in field data this is not possible and instead their impact must be explicitly learned from data and corrected for.

To ensure that comparisons of health between different batteries 2 were like-for-like, internal resistance was estimated as a function of temperature, state of charge, current and time, and then a single set of constant values of temperature, state of charge and current across the entire population was chosen at which to evaluate the health parameter. This can be thought of as learning a function R₀=f (T, I, ĉ, t) from data, using the GP technique described above, and then evaluating or slicing through this function at fixed values of all independent variables apart from time.

As shown in FIG. 10 bottom row, the variability of internal resistance as a function of temperature, current and state of charge is considerable, and if not accounted for would dwarf the variability caused by degradation over time. Each of these projections of the learned function describing R₀ is consistent with battery physics. First, the inverse relationship between internal resistance and temperature is due to the Arrhenius dependence of reaction rate on temperature. Second, since the relationship between reaction rate and overpotential is nonlinear (usually described by Butler-Volmer kinetics), this implies that internal resistance reduces as current increases. Third, the increase in internal resistance with increasing acid concentration/state of charge is likely due to a transport limitation caused by the reduced rate of dissolution of lead-sulfate during charging at high states of charge. Of these effects, the dependency on applied current is key because it has the largest effect on R₀ in the observed operating range, resulting in changes of up to 0.55 Ω, while for temperature and acid concentration the changes in R₀ over the range of observed conditions are only up to 0.07 Ω and 0.13 Ω respectively.

Furthermore, to assess the effect of operating point on R₀, a population-level model was constructed. This was done by generating the GP predictions over a grid of operating points independently for each battery 2 and then combining them using the ‘product of experts’ methodology (see Methods). As we expressed R₀ as a sum of two independent GPs, we made the assumption that these functions are constant through time and across all batteries, with degradation affecting R₀ at all operating points equally.

To highlight the total effect of different batteries 2 in the dataset of the First Example experiencing, on average, different operating conditions, the distribution of R₀ estimates can be estimated over the population at beginning of life for two different operating points.

Firstly, to obtain the lowest variance estimates for each battery independently, the best operating point to choose is its mean operating point. On the other hand, for health prediction (diagnosis and prognosis), a standardised operating point is required for comparability. The following table shows moments (mean and variance) of R₀ distribution across battery population at beginning of life:

| I | T | ĉ | μₚₒₚ(R₀) | σₚₒₚ(R₀) | σ̅ₗ⁻²(R₀) |
|---|---|---|---|---|---|
| (A) | (K) | (mol/m³) | (Ω) | (Ω) | (Ω) |
| 0.96 | 301.0 | 4678 | 0.57 | 0.137 | 1898.0 |
| Īₗ | T̅ₗ | ĉ̅ₗ | 0.64 | 0.198 | 7131.0 |

The variation of R₀ for the common operating point is lower, but the average precision of each estimate is lower, as GPR is used to extrapolate away from the high precision operating points. Thus, employing GP extrapolation means that the average precision of battery R₀ estimates, σ̅ᵢ⁻²(R₀) is lower, but the standard deviation in the mean estimates across the population, σₚₒₚ(R₀), is reduced by 30% using a standardised operating point. The remaining variance across the population reflects cell-to-cell variability at beginning of life. This is the result of manufacturing variations, storage time and conditions prior to deployment of the batteries in the field.

Following normalisation, 1117 R₀ timelines were obtained, calculated at a constant operating point, the population mean. These R₀ estimates, shown in FIGS. 11(a) and 11(b), together with their partial derivative with respect to time, make up our consistent health indicator for each battery in the First Example.

The population level functions R₀ across the operating points were calculated using the product of experts method outlined in [9]. Following the estimation of the posterior distribution of R₀ for each battery 2 independently as described above, predictions on a grid of operating points was performed for all batteries 2. This grid was such that the range for each input variable (temperature, applied current and estimated acid concentration) was varied between its 5th and 95th percentile in turn while keeping the other two constant at the population mean. A precision-weighted sum of forecasts was then calculated for each grid point as per Deisenroth et al. [9], such that

$${μ}_{p} = {σ}_{p}^{2} {\sum }_{k} {β}_{k} {σ}_{k}^{- 2} {μ}_{k}$$

$${σ}_{p}^{- 2} = {\sum }_{k} {β}_{k} {σ}_{k}^{- 2}$$

where βₖ is a even weighting vector such that σₖβₖ=1 and μₖ represents the predicted mean for battery k and σₖ² the predictive variance. Using this method requires very little extra computational effort once the battery-wise posteriors have been calculated as no extra hyperparameters 13 are needed.

To benchmark the approach we consider the same model ([eqn:regression]) but without the dependency of R₀ on the operating point. Furthermore, we assume that R₀ follows a random walk through time, an approach commonly taken in the literature. Using this recursive approach, the tuning parameters are the process and noise covariances as well as the initial variance estimate for R₀, which are often set manually. For consistency with the main approach, we estimate the covariances using maximum likelihood and set the initial variance to be a constant multiple of the process covariance.

FIGS. 11(c)-(e) show similar properties derived in the Second Example.

In the method of FIG. 1, in step S4 stress factors 15 are derived, either from the sensor data 10 or from other sources of information about the battery 2. This is optional, but the stress factors 15 may be used as additional input variables in the classification described below.

The stress factors 15 may be any factor known to affect the health of the battery 2. Suitable types of stress factor are disclosed in [6] and [7]. The stress factors 15 may include any or all of the following non-limitative examples.

The stress factors 15 may include the age of the battery 2. For example, the age of the battery 2 may be defined as the time (in days) since the battery 2 was marked as activated. This stress factor 15 is given the label Age below.

The stress factors 15 may include the cumulative time (or times) that the battery 2 is in a given state (or states) that degrades health. For example, the cumulative times may be calculated by simply summing time increments conditional on the battery 2 being in a specific state, so that

$${\sum }_{S , t} = {\sum }_{S ( t )} Δ t , S ∈ \{ float charge , low V , high V , low T , high T \} ,$$

where S denotes the boolean operator indicating whether the battery is in state S at time t. The definitions of possible states are defined in the following table, where the low and high temperature thresholds represent the 25th and 75th percentiles of the full operating range across the raw data:

| State | Definition |
|---|---|
| float charge | time period > 600 s where 13.4 V < V < 13.6 V |
| low V | V < 12 V |
| high V | V > 14 V |
| low T | T < 24.94° C. |
| high T | T > 31.12° C. |

These stress factors 15 are given the labels Σt_{float}, Σt_{lowV}, Σt_{highV}, Σt_{lowT}, and Σt_{highT} below.

The stress factors 15 may include the absolute cumulative charge count through the lifetime of the battery. For example, this may be calculated by Coulomb counting, using a similar method to that described above for step S1, but through the entire lifetime of the battery 2. This stress factor 15 is given the label ΣAh below.

The stress factors 15 may include a count of the number of the discharge cycles. For example, this may be done by counting discharge segments defined by any continuous discharge period of over a predetermined period (e.g. 600 s in the First Example) where the discharge current is greater than predetermined threshold (e.g. 0.05 A in the First Example). This stress factor 15 is given the label Σcyc below.

The health metrics 13 produced in the method of FIG. 1 provide information on the state of health of the batteries 2 in the set. As such, they may be used in a variety of ways to inform maintenance of the batteries 2. One possible use is to as an input variable, optionally in addition to one or more of the stress factors 15, to a machine learning classifier that classifies the batteries 2 into two or more classifications representing presence and absence of predicted faults. Example of methods of predicting faults of batteries 2 using such a machine learning classifier that is a Gaussian Process classifier are shown in FIGS. 12 and 13.

In each of FIGS. 12 and 13, test sensor data 10b is received from batteries 2 in a test set. The test sensor data 10b is processed using the method of FIG. 1 and specifically steps S1-S4 that operate as described above to produce operational parameters 11b, posterior predictive distributions 12b, test health metrics 14b and test stress factors 15b.

The difference between FIGS. 12 and 13 is as follows.

In FIG. 12, the hyperparameters are test hyperparameters 13b the are specific to each battery 2, so are fitted over the test sensor data 10b of respective batteries 2 in the test set, thereby forming an output of step S2 in FIG. 12.

In contrast, in FIG. 13, the hyperparameters are training hyperparameters 13a that are common to all batteries in the training set and the test set. Thus, the training hyperparameters 13a may be previously derived using the method shown in FIG. 1 performed on training sensor data 10a received from batteries 2 in a training set and are supplied as an input to step S2 in FIG. 13.

In step S5, the test health metrics 14b and optionally also the test stress factors 15b are used as input variables by a Gaussian Process classifier that classifies the batteries 2 in the test set into a plurality of classifications representing presence and absence of predicted faults. As mentioned above, the prediction may be prediction of a current fault (i.e. diagnosis of the current state) or a future fault (i.e. prognosis of a future state).

Although a Gaussian Process classifier implemented in FIGS. 12 and 13, this is not limitative and more generally any other type of machine learning classifier could alternatively be employed, as also discussed above.

The Gaussian Process classifier implemented in step S5 also receives corresponding data in respect of batteries 2 in a training set. This data comprises training health metrics 14a, training stress factors 14b (in the optional case that test stress factors 15b are used for the test set), and training classification labels 16.

The training health metrics 14a are derived using the method shown in FIG. 1 performed on training sensor data 10a received from batteries 2 in the training set. In the case of FIG. 12, the training hyperparameters 13a are specific to each battery 2, so are fitted over the training sensor data 10b of respective batteries 2 in the training set. In the case of FIG. 13, the training hyperparameters 13a are common to each battery 2 in the training set, so are fitted over the training sensor data 10a of all the batteries 2 in the training set, as already described above.

The test stress factors 15b are of the same type as the training stress factors 15b, so are produced in step S4 using the same calculation.

The training classification labels 16 represent the classifications of the batteries 2 in the training set. The assignment of labels is performed by the user based on real-world information about the presence or absence of faults in the batteries 2 in the training set, for example derived from maintenance and repair records. In the simplest case, there may be two classifications representing the presence and absence of faults respectively. To provide more detailed fault information, plural classifications may represent the presence of different types or magnitude of faults. Similarly, plural classifications may represent different states that exist in the absence of faults.

The Gaussian Process classifier implemented in step S5 may use a standard GP classification framework [3]. For example, the GP classifier may implement an SE covariance function with automatic relevance detection,

$${k}_{class} ( x , {x}^{′} ) = {σ}_{f}^{2} exp ( {\sum }_{x} - \frac{{( x - {x}^{′} )}^{2}}{2 {l}_{x}^{2}} )$$

with an uniform hyperprior. Maximum likelihood estimates may then be obtained by minimizing the negative log marginal likelihood of the data, for example using the L-BFGS-B algorithm in the scikit-learn implementation of the GP classifier [12].

In order to understand the evolution of battery health at a population level for the solar-connected lead-acid batteries 2, the correlation was measured between the health metrics 13 and stress factors 15 known to affect battery life. These consisted of battery calendar age, total times spent at floating charge, low voltage, high voltage, low temperature and high temperature, as well as total Ampere hour throughput and cycle count (see SI for calculation). The following table shows the matrix of the Pearson correlation coefficients calculated over the battery population at the end of the data series for each battery, where the summation is the cumulative sum up to the point of prediction:

| | | ∂R₀/ | | Σ | Σ | Σ | Σ | Σ | Σ | Σ |
|---|---|---|---|---|---|---|---|---|---|---|
| | R₀ | ∂t | Age | Ah | cyc | t_{float} | t_{lowV} | t_{highV} | t_{lowT} | t_{highT} |
| R₀ | 1.00 | 0.75 | 0.25 | 0.03 | 0.18 | 0.07 | 0.13 | 0.04 | 0.15 | −0.15 |
| ∂R₀/∂t | 0.75 | 1.00 | 0.14 | 0.25 | 0.17 | −0.06 | 0.06 | 0.04 | −0.01 | 0.01 |
| Age | 0.25 | 0.14 | 1.00 | 0.29 | 0.42 | 0.29 | 0.05 | 0.37 | 0.17 | −0.04 |
| Σ Ah | 0.03 | 0.25 | 0.29 | 1.00 | 0.36 | −0.33 | 0.11 | 0.33 | −0.25 | 0.34 |
| Σ cyc | 0.18 | 0.17 | 0.42 | 0.36 | 1.00 | −0.17 | 0.00 | −0.05 | 0.28 | −0.22 |
| Σ t_{float} | 0.07 | −0.06 | 0.29 | −0.33 | −0.17 | 1.00 | −0.17 | 0.21 | −0.36 | 0.02 |
| Σ t_{lowV} | 0.13 | 0.06 | 0.05 | 0.11 | 0.00 | −0.17 | 1.00 | −0.10 | 0.00 | −0.05 |
| Σ t_{highV} | 0.04 | 0.04 | 0.37 | 0.33 | −0.05 | 0.21 | −0.10 | 1.00 | −0.24 | 0.36 |
| Σ t_{lowT} | 0.15 | −0.01 | 0.17 | −0.25 | 0.28 | −0.36 | 0.00 | −0.24 | 1.00 | −0.68 |
| Σ t_{highT} | −0.15 | 0.01 | −0.04 | 0.34 | −0.22 | 0.02 | −0.05 | 0.36 | −0.68 | 1.00 |

Although the correlation coefficient does not accurately capture non-linear effects, it is clear that the health metrics R₀ and ∂R₀/∂t are very related, which implies the existence of the knee-point in degradation. Both in turn are most correlated with battery age, followed by the cycle count. Also, the signs of the correlation coefficients between health and time spent at elevated temperature and low temperatures, Σ t_{highT} and Σ t_{lowT} respectively, imply that higher temperature within the operating range experienced in the dataset improves lifetime. In general, the effect of temperature on degradation in lead-acid systems is not straightforward, as slightly elevated temperatures, especially during charging, may improve lifetime due to improved solubility of lead sulfate. On the other hand, elevated temperatures increase the rate of grid corrosion in the electrodes.

Moreover, the correlation matrix shows the variability in usage across the battery population, as stress factors in general have low (<40%) cross correlation. This clearly illustrates the advantage of large field datasets in understanding the evolution of battery health, as creating a comparable variety of operating conditions in laboratory conditions would be prohibitively expensive and time-consuming.

In the First Example, the following was performed to establish the efficacy of the approach.

The augmented input matrix for the GP classifier in step S5 for fault prediction consisted of the meath metrics 13

$$( {R}_{0} , \frac{\partial {R}_{0}}{\partial t} )$$

and the stress factors 15 indicated above and known to affect battery state of health. The health metrics 13

$$( {R}_{0} , \frac{\partial {R}_{0}}{\partial t} )$$

were obtained by forward-propagating the Kalman filter [8] from the last observed charging segment to the appropriate point in time, preceding the end of the time series

In laboratory based environments, the diagnosis of battery health is commonly done using reference performance tests (RPTs) such as current pulse tests for internal resistance, or constant current discharge at constant temperature to determine capacity. Due to the unavailability of such tests in the dataset of the First Example, the validation of diagnosis and prognosis of battery failure had to be performed indirectly. In order to formulate both tasks as a supervised machine learning problem, there were derived classification labels 17 for the batteries 2 indicating the battery 2 as faulty/non-faulty depending on whether they had been called in for repair at the end of the data series. When a unit is returned to a workshop for repair, the data is timestamped and reasons for the repair are indicated in the database. However, this labelling suffers from the drawback that the need for repair is customer driven and as such is affected by individual decisions. This is a major source of uncertainty which is expected to result in an increased number of both false positives and false negatives in the classifier. Using this approach, the dataset contained 464 units that had entered repair (i.e. were faulty) at the end of the time series and 653 that had not.

Given the labelled dataset, diagnosis and prognosis were considered in a similar manner, with the difference that pure diagnosis consists of classification at the end of each data series while prognosis consists of performing the classification ahead of time. To this end, we performed prognosis by cutting off the data at 2, 4, 6 and 8 weeks before the end of recorded data and fitted the hyperparameters and posteriors, followed by classification using the same labelling as we did for diagnosis.

Three cases for prognosis and diagnosis were considered. Following the implementation, a benchmark test was performed by considering a ‘naive’ approach to estimating R₀, whereby normalisation was not applied with respect to operating conditions and the internal resistance is modelled as a random walk. This method is commonly employed in literature. Finally, diagnosis and prognosis were performed with an augmented model, which consisted of the diagnosis model with the known stress factors as extra inputs. In each case, 5-fold cross-validation was stratified to split the data into training and test sets and the performance numbers reported are the test set average.

For the diagnosis case (prediction of a current failure), only these two inputs R₀,

$$\frac{\partial {R}_{0}}{\partial t}$$

were used, with only the value of R₀ available for the benchmark, considering R₀ a random walk.

For the prognosis case (prediction of a future failure), the diagnosis inputs were augmented with cumulative stress factors including X.

The inputs listed above were fed into the GP classifier.

The performance metrics chosen for the classifier were such that the unevenness in labelling (653 non-faulty, 464 faulty) was taken into account.

The balanced accuracy metric was calculated as the average of classifier sensitivity and specifity, so that

$$Balanced accuracy = \frac{1}{2} ( Sensitivity + Specifity ) = \frac{1}{2} ( \frac{TP}{TP + FN} + \frac{TN}{TN + FP} ) ,$$

where TP, TN, FP, FN represent the true positive, true negative, false positive and false negative rates respectively. The alternative metric used, the Bayes factor, indicates the ratio between posterior and prior odds of battery failure and is calculated as

$$Bayes Factor = \frac{S ensitivity}{1 - Specificity} = \frac{TP * ( FP + TN )}{FP * ( TP + FN )}$$

The summary statistics for classifier performance grouped by the classification time horizon and method are illustrated in FIG. 14. All performance metrics reported are the average for the test sets using stratified 5-fold cross validation for each test case.

The following table summarises GP Classifier performance statistics using the augmented inputs over the five forecasting horizons, the balanced accuracies and Bayes factors reported being the mean for the stratified 5-fold cross validation test set:

| Days | | | | | Balanced | Bayes |
|---|---|---|---|---|---|---|
| before | TP | FP | FN | TN | Accuracy (%) | Factor |
| 0 | 370 | 56 | 94 | 597 | 85.6 | 9.3 |
| 14 | 359 | 57 | 105 | 596 | 84.3 | 8.9 |
| 28 | 336 | 62 | 128 | 591 | 81.5 | 7.6 |
| 42 | 355 | 65 | 109 | 588 | 83.3 | 7.7 |
| 56 | 333 | 77 | 131 | 576 | 80.0 | 6.1 |

The full performance comparison over all input sets and time horizons is shown in the following table:

| | | | | | | Balanced | |
|---|---|---|---|---|---|---|---|
| Days | | | | | | Accuracy | Bayes |
| before | Classifier input | TP | FP | FN | TN | (%) | Factor |
| 0 | R benchmark | 221 | 82 | 243 | 571 | 67.5 | 3.8 |
| 0 | $R , \frac{\partial R}{\partial t}$ | 309 | 85 | 155 | 568 | 76.8 | 5.1 |
| 0 | $R , \frac{\partial R}{\partial t} , stress factors$ | 370 | 56 | 94 | 597 | 85.6 | 9.3 |
| 14 | R benchmark | 161 | 75 | 303 | 578 | 61.6 | 3.0 |
| 14 | $R , \frac{\partial R}{\partial t}$ | 261 | 82 | 203 | 571 | 71.8 | 4.5 |
| 14 | $R , \frac{\partial R}{\partial t} , stress factors$ | 359 | 57 | 105 | 596 | 84.3 | 8.9 |
| 28 | R benchmark | 126 | 60 | 338 | 593 | 59.0 | 3.0 |
| 28 | $R , \frac{\partial R}{\partial t}$ | 241 | 85 | 223 | 568 | 69.5 | 4.0 |
| 28 | $R , \frac{\partial R}{\partial t} , stress factors$ | 336 | 62 | 128 | 591 | 81.5 | 7.6 |
| 42 | R benchmark | 104 | 49 | 360 | 604 | 57.5 | 3.0 |
| 42 | $R , \frac{\partial R}{\partial t}$ | 209 | 87 | 255 | 566 | 65.9 | 3.4 |
| 42 | $R , \frac{\partial R}{\partial t} , stress factors$ | 355 | 65 | 109 | 588 | 83.3 | 7.7 |
| 56 | R benchmark | 75 | 63 | 389 | 590 | 53.3 | 1.7 |
| 56 | $R , \frac{\partial R}{\partial t}$ | 172 | 92 | 292 | 561 | 61.5 | 2.6 |
| 56 | $R , \frac{\partial R}{\partial t} , stress factors$ | 333 | 77 | 131 | 576 | 80.0 | 6.1 |

The improvement in performance between the benchmark classifier and using SoH metric calculated through the method in the First Example is 9.3% in terms of balanced accuracy. This translates to an increase in the Bayes factor from 3.8 to 5.1However, this is yet improved by the incorporation of the stress factors 15, yielding a balanced accuracy of 85.6%. As well as balanced accuracy, the Bayes factor, that is the positive likelihood ratio of the classifier is reported. This reflects the ratio of the posterior odds of a fault given a faulty diagnosis with respect to the baseline (prior) odds without employing the classifier.

For both the diagnostic and prognostic cases, the augmented model performs considerably better with a margin of over 8.8% in terms of balanced accuracy for diagnosis and has less deterioration in performance as the time horizon of fault forecasting increases, showing a 5.6% range from 0-8 weeks where the normal model's performance deteriorates by 15.3%.

Clearly, the health metric 15 by itself becomes less informative the further a battery 2 is from end-of-life, as the onset of rapid degradation has not occurred and internal resistance together with its rate of change over time are more homogeneous across the population. In contrast, the non-linear relation between cumulative stress and health evolution is better captured by the classifier using the augmented input set.

The importance of each input over the multiple forecasting horizons is shown in the following table, which shows the average of maximum likelihood estimates of length scales in the GP classifier across cross-validation sets for each input for all forecasting horizons considered., the inverse length scale reflecting the importance of each input. Σ tₓ stands for cumulative time spent in state x:

| | | | ∂R₀/ | | Σ | Σ | Σ | Σ | Σ | Σ | Σ |
|---|---|---|---|---|---|---|---|---|---|---|---|
| Horizon | σ_{f}² | R₀ | ∂t | Age | Ah | cyc | t_{float} | t_{lowV} | t_{highV} | t_{lowT} | t_{highT} |
| 0 | 3.54 | 1.23 | 1.14 | 0.42 | 3.14 | 8.78 | 7.22 | 2.16 | 7.44 | 3.50 | 2.99 |
| 2 | 3.87 | 1.48 | 3.24 | 0.49 | 3.57 | 4.59 | 4.84 | 2.29 | 10.74 | 4.64 | 2.87 |
| 4 | 3.99 | 1.33 | 4.37 | 0.33 | 3.78 | 4.54 | 5.51 | 2.32 | 9.63 | 4.12 | 3.22 |
| 6 | 3.73 | 1.47 | 1.96 | 0.31 | 1.74 | 3.12 | 4.79 | 2.95 | 7.81 | 3.65 | 1.02 |
| 8 | 3.57 | 1.26 | 2.39 | 0.18 | 1.53 | 2.96 | 6.88 | 2.89 | 6.62 | 2.37 | 1.30 |

Using a kernel with automatic relevance determination in the classifier, the inverse length scales for each input reflect their importance in the classifier. Battery age is clearly the most important across all forecasting horizons, with the estimate for R₀ second in most cases. Least important on average are the total time spent in floating charge and high voltage, which we defined as periods where terminal voltage was above 14 V. Thus, in the First Example, a data-driven model for state-of-health estimation of battery energy storage systems using real-world operating data at a large scale is introduced. Informed by physics, the machine learning method successfully captures the dependency of battery internal resistance on current, temperature, state of charge as predicted by detailed electrochemical models. By tracking internal resistance at a constant operating point through the lifetime of a battery, using an appropriate Gaussian Process kernel allowed construction of a consistent, comparable health metric for 1117 lead-acid batteries in our dataset. By validating our health metric against repair data obtained from the BESS provider, it was found to overperform the common approach whereby internal resistance is not normalised with respect to the operating point and is assumed to follow a random walk. In addition, it was found that conditioning the forecast of a fault occurring with stress factors affecting battery life leads to improved accuracy. The augmented model achieved a balanced accuracy of 80% in classifying batteries as faulty 8 weeks prior to repair.

FIG. 15 illustrates a method of servicing the batteries 2 showing how the techniques described herein may be used. As above, this method may be generalised to any type of electrochemical energy supply clement. The method is performed as follows.

In step S10, faults of batteries 2 in a test set are predicted. This step may be performed using the method as shown in either of FIGS. 12 or 13.

In step S11, the batteries 2 in the test set are serviced on the basis of the classifications derived in step S10. In general any type of servicing may be performed, for example repairing or replacing electrochemical energy supply elements in classifications representing the presence of a predicted fault. Where plural classifications represent the presence of different types or magnitude of faults, the servicing may be varied on the basis of the type or magnitude of the fault. Where plural classifications represent different states that exist in the absence of faults, the servicing may include pre-emptive servicing on the basis of the state.

### REFERENCES

[1] R. R. Richardson, C. R. Birkl, M. A. Osborne, and D. A. Howey, “Gaussian Process Regression for in Situ Capacity Estimation of Lithium-Ion Batteries,” IEEE Transactions on Industrial Informatics, vol. 15, no. 1, pp. 127-138, 2019, doi: 10.1109/Tll.2018.2794997.
[2] G. You, S. Park, and D. Oh, “Real-time state-of-health estimation for electric vehicle batteries: A data-driven approach,” Applied Energy, vol. 176, pp. 92-103, Aug. 2016, doi: 10.1016/J.APENEROY.2016.05.051.
[3] C. E. Rasmussen and C. K. I. Williams, Gaussian Processes for machine learning. Cambridge, Mass. ; London: MIT, 2006.

[4] S. Särkkä and J. Hartikainen, “Infinite-dimensional kalman filtering approach to spatio-temporal Gaussian Process regression,” Journal of Machine Learning Research, vol. 22, pp. 993-1001, 2012.
[5] S. Särkkä, A. Solin, and J. Hartikainen, “Spatiotemporal learning via infinite-dimensional bayesian filtering and smoothing: A look at Gaussian Process regression through kalman filtering,” IEEE Signal Processing Magazine, vol. 30, no. 4, pp. 51-61, 2013, doi: 10.1109/MSP.2013.2246292.
[6] P. Ruetschi, “Aging mechanisms and service life of lead-acid batteries,” Journal of Power Sources, vol. 127, no. 1-2, pp. 33-44, 2004, doi: 10.1016/j.jpowsour.2003.09.052.
[7] J. Schiffer, D. U. Sauer, H. Bindner, T. Cronin, P. Lundsager, and R. Kaiser, “Model prediction for ranking lead-acid batteries according to expected lifetime in renewable energy systems and autonomous power-supply systems,” Journal of Power Sources, vol. 168, no. 1 SPEC. ISS., pp. 66-78, 2007, doi: 10.1016/j.jpowsour.2006.11.092.
[8] Arno Solin, “Stochastic Differential Equation Methods for Spatio-Temporal Gaussian Process Regression,” PhD thesis, Aalto University, 2016.
[9] M. P. Deisenroth and J. W. Ng, “Distributed Gaussian Processes,” 32nd International Conference on Machine Learning, ICML 2015, vol. 2, pp. 1481-1490, 2015, doi: 10.25561/21163.
[10] R. E. Carlson and F. N. Fritsch, “Monotone piecewise cubic interpolation,” SIAM J Numer. Anal., vol. 17, no. 2, pp. 238-246, 1980.
[11] J. Hartikainen and S. Särkkä, “Kalman filtering and smoothing solutions to temporal Gaussian Process regression models,” Proceedings of the 2010 IEEE International Workshop on Machine Learning for Signal Processing, MLSP 2010, no. Mlsp, pp. 379-384, 2010, doi: 10.1109/MLSP.2010.5589113.
[12] F. Pedregosa et al., “Scikit-learn: Machine Learning in {P}ython,” Journal of Machine Learning Research, vol. 12, pp. 2825-2830, 2011.
[13] Arno Solin, “Stochastic Differential Equation Methods for Spatio-Temporal Gaussian Process Regression,” PhD thesis, Aalto University, 2016.
[14] I. S. Mbalawata, S. Särkkä, and H. Haario, “Parameter estimation in stochastic differential equations with Markov chain Monte Carlo and non-linear Kalman filtering,” Computational Statistics, vol. 28, no. 3, pp. 1195-1223, 2013, doi: 10.1007/s00180-012-0352-y.
[15] H. E. Rauch, F. Tung, and C. T. Striebel, “Maximum likelihood estimates of linear dynamic systems,” AIAA Journal, vol. 3, no. 8, pp. 1445-1450, 1965, doi: 10.2514/3.3166.
[16] Jöst, D., Ringbeck, F., Blömeke, A., & Sauer, D. U. (2021). Timeseries data of a drive cycle aging test of 28 high energy NCA/C+Si round cells of type 18650. https://doi.org/10.18154/RWTH-2021-02814

1. A method of determining health of electrochemical energy supply elements in a set of electrochemical energy supply elements, the method comprising
receiving sensor data representing sensed parameters of the electrochemical energy supply elements over time;
fitting a model of a health parameter of respective electrochemical energy supply elements over the sensor data, the health parameter being dependent on operational parameters over time derivable from the sensor data and on health of the electrochemical energy supply element, the model modelling the distribution of the health parameter as a Gaussian Process having an overall kernel that combines a first kernel that models dependency of the health parameter on the operational parameters and a second kernel that is a non-stationary kernel that models degradation of the health parameter over time; and
deriving health metrics over time for respective electrochemical energy supply elements comprising values of the health parameter that are predicted by the fitted model in respect of a predetermined operating point of the operational parameters.

2. The method according to claim 1, wherein the first kernel is a stationary kernel, preferably a kernel in the the Matern family of kernels, more preferably a squared exponential kernel.

3. The method according to claim 1, wherein the second kernel is a kernel representing any order of integration of the Wiener Process or a polynomial kernel of any order.

4. The method according to claim 1, wherein the step of fitting the model of the health parameter is performed using a recursive estimation framework.

5. The method according to claim 1, wherein the step of fitting the model of the health parameter outputs a posterior predictive distribution of the health parameter.

6. The method according to claim 1, wherein the step of fitting the model of the health parameter outputs a posterior estimate of hyperparameters of the overall kernel.

7. The method according to claim 5, wherein either:
the hyperparameters are common to all the electrochemical energy supply elements and are either fitted over the sensor data of all the electrochemical energy supply elements in the set;
the hyperparameters are common to all the electrochemical energy supply elements and have predetermined values; or the hyperparameters are specific to each electrochemical energy supply element and fitted over the sensor data of respective electrochemical energy supply elements in the set.

8. The method according to claim 1, wherein the overall kernel that combines the first kernel and the second non-stationary kernel by addition or multiplication.

9. The method according to claim 1, wherein the values comprise absolute values of the health parameter.

10. The method according to claim 1, wherein the values comprise partial derivatives of the health parameter with respect to time.

11. The method according to claim 1, wherein the health parameter is internal resistance or capacity.

12. The method according to claim 1, wherein the sensed parameters comprise voltage, current and temperature.

13. The method according to claim 1, wherein the operational parameters comprise current, temperature and a state of charge.

14. The method according to claim 13, wherein the state of charge is a material property, for example a concentration of material in the electrochemical energy supply element.

15. The method according to claim 13, further comprising deriving the state of charge from the sensed electrical parameters, optionally using Coulomb counting.

16. The method according to claim 1, further comprising selecting segments of the sensor data that represent charging of the electrochemical energy supply element, the step of fitting the model of the health parameter comprising fitting the model of the health parameter to the selected segments of the sensor data.

17. The method according to claim 1, wherein the electrochemical energy supply element is a battery element, for example a battery cell, a battery module, or an assembly of battery modules.

18. The method according to claim 17, wherein the battery element is a lead-acid battery element or a lithium-ion battery element.

19. The method of predicting faults of electrochemical energy supply elements in a test set, the method comprising:
performing a method according to claim 1 in respect of the electrochemical energy supply elements in the test set, and
classifying the electrochemical energy supply elements with a machine learning classifier that uses the derived the health metrics over time as input variables, into a plurality of classifications representing presence and absence of predicted faults.

20. The method according to claim 19, further comprising deriving values of at least one stress factor for respective electrochemical energy supply elements, the at least one stress factor being a factor affecting the health of the electrochemical energy supply element, the machine learning classifier classifying the electrochemical energy supply elements on the basis of both the derived the health metrics and the values of the at least one stress factor.

21. The method according to claim 19, wherein the machine learning classifier comprises a Gaussian Process classifier that uses health metrics over time and classification labels in respect of electrochemical energy supply elements in a training set.

22. The method according to claim 21, further comprising performing the method of determining health of electrochemical energy supply elements in a set of electrochemical energy supply elements in respect of the electrochemical energy supply elements in the training set, the health metrics derived thereby being the health metrics over time in respect of electrochemical energy supply elements in a training set used by the Gaussian Process classifier.

23. The method according to claim 19, further comprising servicing the electrochemical energy supply elements in the test set on basis of the classifications.

24-26. (canceled)

27. A non-transitory computer-readable medium embodying a program executable in at least one computing device, comprising code that upon execution performs a method according to claim 1.

28. A system or apparatus, comprising:
at least one computing device having a processor and a memory; and
at least one application executable in the at least one computing device stored in the memory that, when executed by the processor, the application causes the at least one computing device to perform a method according to claim 1.
